(19) United States
(12) Patent Application Publication
(10) Pub. No.: US 2024/0121973 A1
(43) Pub. Date: Apr. 11, 2024

(54) COMPOSITION AND ORGANIC LIGHT-EMITTING ELEMENT

(71) Applicants: KYUSHU UNIVERSITY, NATIONAL UNIVERSITY CORPORATION, Fukuoka-shi, Fukuoka (JP); KYULUX, INC., Fukuoka-shi, Fukuoka (JP)

(72) Inventors: Hajime NAKANOTANI, Fukuoka-shi, Fukuoka (JP); Thanh Ba NGUYEN, Fukuoka-shi, Fukuoka (JP); Chihaya ADACHI, Fukuoka-shi, Fukuoka (JP); Hayato KAKIZOE, Fukuoka-shi, Fukuoka (JP); Ayataka ENDO, Fukuoka-shi, Fukuoka (JP)

(21) Appl. No.: 17/767,622

(22) PCT Filed: Oct. 6, 2020
(86) PCT No.: PCT/JP2020/037808

§ 371 Date: Apr. 8, 2022

(30) Foreign Application Priority Data
Oct. 10, 2019 (JP) 2019-186950

(51) Int. Cl. H10K 50/11; C09K 11/06; H10K 85/60

(52) U.S. Cl. CPC H10K 50/11; C09K 11/06; H10K 85/631; H10K 85/6572

(57) ABSTRACT

When ΔE_{ST} of at least one of a donor compound and an acceptor compound to form an exciplex is 0.35 eV or less, the driving lifetime of an exciplex light-emitting device can be improved.

### TECHNICAL FIELD

The present invention relates to a composition useful as a material for a light-emitting layer, and an organic light-emitting device using the composition.

### BACKGROUND ART

Studies for enhancing the light emission efficiency of organic light-emitting devices such as organic electroluminescent devices (organic EL devices) are being made actively. In particular, various kinds of efforts have been made for increasing light emission efficiency by effectively utilizing the energy in an excited triplet state that is lost by thermal deactivation in ordinary organic compounds. Among them, there are seen studies relating to an organic electroluminescent device utilizing an exciplex formed between a donor molecule and an acceptor molecule.

An exciplex is an excited state to be formed between two molecules by charge transfer from a donor molecule to an acceptor molecule when one of the donor molecule and the acceptor molecule has become an excited state. In an exciplex, the difference ΔE_{ST} between the excited singlet energy level E_{S1} and the excited triplet energy level E_{T1} is small owing to spatial separation between HOMO (highest occupied molecular orbital) of a donor molecule and LUMO (lowest unoccupied molecular orbital) of an acceptor molecule, and therefore reverse intersystem crossing from an excited triplet state to an excited singlet state occurs readily. Consequently, by utilizing an exciplex, an excited triplet energy can be efficiently transferred to an excited singlet energy and the energy can be effectively utilized for light emission to thereby improve the light emission efficiency of an organic light-emitting device.

### CITATION LIST

### Non-Patent Literature

NPL 1: D. D. Zhang, etc., ACS Appl. Mater. Interfaces. 2016, 8, 3825

### SUMMARY OF INVENTION

### Technical Problem

As described above, the light emission efficiency of an organic light-emitting device can be improved by utilizing an exciplex. However, regarding the organic light-emitting device using an exciplex (exciplex light-emitting device), driving stability of the device has not been investigated sufficiently, and heretofore with conventional material constitutions, there is a problem in that the driving lifetime cannot reach a practical level

NPL 1 describes that the driving lifetime is improved by devising the device configuration of the exciplex light-emitting device. However, in the organic light-emitting device described in NPL 1, since the device configuration is greatly changed from conventional ones, there is a problem in that the donor compound and the acceptor compound usable therein are limited and the latitude in material selection is narrow.

Given the situation, the present inventors have made assiduous studies for the purpose of developing a combination of a donor compound and an acceptor compound capable of prolonging the driving lifetime of an exciplex light-emitting device.

### Solution to Problem

As a result of assiduous studies, the present inventors have found that, by using a combination of a donor compound and an acceptor compound capable of satisfying specific energy relationship, an exciplex light-emitting device having a prolonged driving lifetime can be realized. The present invention has been made on the basis of this finding, and specifically has the following constitution.

[1] A composition containing a donor compound and an acceptor compound to form an exciplex, and satisfying the following requirement A and requirement B1.

### (Requirement A)

The donor compound or the acceptor compound is such that the difference between the lowest excited triplet energy level and the lowest excited singlet energy level thereof, ΔE_{ST} is 0.35 eV or less.

### (Requirement B1)

The lowest excited triplet energy level E_{T1}(EX) of the exciplex and the excited triplet energy level E_{T1}(M) of the donor compound or the acceptor compound satisfying the requirement A satisfy the following relational expression (unit, eV).

E_{T1}(EX)−0.2≤E_{T1}(M)≤E_{T1}(EX)

[2] A composition containing a donor compound and an acceptor compound to form an exciplex, and satisfying the following requirement A and requirement B2.

### (Requirement A)

The donor compound or the acceptor compound is such that the difference between the lowest excited triplet energy level and the lowest excited singlet energy level thereof, ΔE_{ST} is 0.35 eV or less.

### (Requirement B2)

The phosphorescence emitted from the composition is a phosphorescence from the donor compound or the acceptor compound.

[3] The composition according to [1] or [2], wherein the acceptor compound satisfies the requirement A.
[4] The composition according to any one of [1] to [3], wherein the acceptor compound has a group having a negative Hammett's σp value.
[5] The composition according to any one of [1] to [4], wherein the acceptor compound has a heteroaromatic ring containing a nitrogen atom as a ring skeleton-constituting atom, and a substituted or unsubstituted diarylamino group.
[6] The composition according to [5], wherein the acceptor compound has a structure represented by the following formula (1).

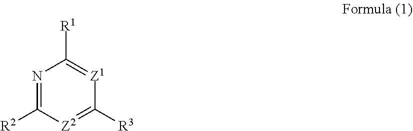

In the formula (1), Z¹ represents N or C(R⁴), Z² represents N or C(R⁵), R¹ to R⁵ each independently represent a hydrogen atom, CN, a substituted or unsubstituted alkyl group, a substituted or unsubstituted aryl group, or a substituted or unsubstituted heteroaryl group, and at least one of R¹ to R⁵ is a group having a substituted or unsubstituted diarylamino group.

[7] The composition according to [6], wherein at least one of R¹ to R⁵ is a group represented by the following formula (2).

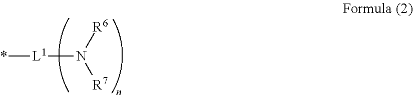

In the formula (2), R⁶ and R⁷ each independently represent a substituted or unsubstituted aryl group, L¹ represents a single bond, or a substituted or unsubstituted arylene group, n represents an integer of 1 or more and not more than the maximum number which can be substituted for L¹, * indicates the position bonding to the heteroaromatic ring in the formula (1).

[8] The composition according to [6] or [7], wherein the acceptor compound has two or more substituted or unsubstituted diarylamino groups in the molecule.
[9] The composition according to [6] or [7], wherein the acceptor compound has three or more substituted or unsubstituted diarylamino groups in the molecule.
[10] The composition according to any one of [1] to [9], wherein the donor compound does not have a group having a Hammett's σp value of 0.2 or more.
[11] The composition according to any one of [1] to [9], wherein the donor compound does not have a group having a positive Hammett's σp value.
[12] The composition according to any one of [1] to [11], wherein the donor compound has two or more triarylamine partial structures.
[13] The composition according to [12], wherein the donor compound has a structure represented by the following formula (3).

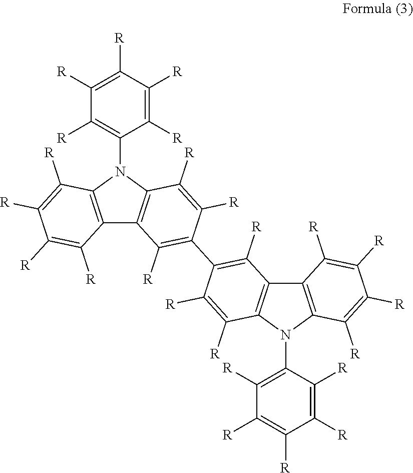

In the formula (3), R each independently represents a hydrogen atom or a substituent.

[14] The composition according to any one of [6] to [13], wherein Z¹ and Z² are N.
[15] The composition according to any one of [1] to [14], further containing a fluorescent compound.
[16] The composition according to [15], wherein the lowest excited triplet energy level E_{T1}(F) of the fluorescent compound and the excited triplet energy level E_{T1}(M) of the donor compound or the acceptor compound satisfying the requirement A satisfy the following relational expression (unit, eV).

E_{T1}(M)≤E_{T1}(F)

[17] The composition according to [16], wherein the lowest excited triplet energy level E_{T1}(F) of the fluorescent compound and the excited triplet energy level E_{T1}(A) of the acceptor compound satisfying the requirement A satisfy the following relational expression (unit, eV).

E_{T1}(F)−0.2≤E_{T1}(M)≤E_{T1}(F)

[18] The composition according to any one of [15] to [17], wherein the lowest excited singlet energy level E_{S1}(EX) of the exciplex, the lowest excited singlet energy level E_{S1}(F) of the fluorescent compound, the energy Eₚₑₐₖ(EX) obtained from the maximum emission wavelength of the exciplex, and the energy Eₚₑₐₖ(F) obtained from the maximum emission wavelength of the fluorescent compound all satisfy the following relational expressions (unit eV).

E_{S1}(F)<E_{S1}(EX)

Eₚₑₐₖ(EX)<Eₚₑₐₖ(F)

[19] The composition according to any one of [1] to [18], which is filmy.
[20] An organic light-emitting device having a light-emitting layer which contains the composition of any one of [1] to [19].
[21] The organic light-emitting device according to [20], which emits delayed fluorescence.

### Advantageous Effects of Invention

The composition of the present invention can realize stable light emission by forming an exciplex. The organic light-emitting device which contains the composition of the present invention in the light-emitting layer can stably maintain light emission by exciplex and can realize a long driving lifetime.

### BRIEF DESCRIPTION OF DRAWINGS

FIG. 1 This is a schematic view for explaining the light emission mechanism of the composition of the present invention.

FIG. 2 This is a schematic cross-sectional view showing a layer configuration example of an organic electroluminescent device.

FIG. 3 This is a graph showing driving time dependency of the emission intensity of organic electroluminescent devices each using a compound D1 as a donor compound and using any of compounds A1 to A6 as an acceptor compound

### DESCRIPTION OF EMBODIMENTS

The contents of the invention will be described in detail below. The constitutional elements may be described below with reference to representative embodiments and specific examples of the invention, but the invention is not limited to the embodiments and the examples. In the description herein, a numerical range expressed as “to” means a range that includes the numerical values described before and after “to” as the upper limit and the lower limit. The hydrogen atom that is present in the molecule in the compound used in the invention is not particularly limited in isotope species, and for example, all the hydrogen atoms in the molecule may be ¹H, and all or a part of them may be ²H (deuterium (D)).

### <Composition (First Composition)>

The composition of the present invention contains a donor compound and an acceptor compound to form an exciplex, and satisfies the following requirement A and requirement B1.

### (Requirement A)

The donor compound or the acceptor compound is such that the difference between the lowest excited triplet energy level and the lowest excited singlet energy level thereof, ΔE_{ST} is 0.35 eV or less.

### (Requirement B1)

The lowest excited triplet energy level E_{T1}(EX) of the exciplex and the excited triplet energy level E_{T1}(M) of the donor compound or the acceptor compound satisfying the requirement A satisfy the following relational expression (unit, eV).

E_{T1}(EX)−0.2≤E_{T1}(M)≤E_{T1}(EX)

In the present invention, “a donor compound and an acceptor compound to form an exciplex” means a combination of compounds of a donor compound and an acceptor compound which, when one of the donor compound and the acceptor compound is in an excited state, the compounds can form an excited complex by charge transfer from the donor compound to the acceptor compound, and “exciplex” means an excited state of the excited complex. The combination of a donor compound and an acceptor compound to form an exciplex can be confirmed by the fact that the emission spectrum observed in a mixed film of the donor compound and the acceptor compound shows a pattern different from that of at least one of the emission spectrum observed in a single film of the donor compound and the emission spectrum observed in a single film of the acceptor compound. In the case where the emission spectrum of a mixed film is derived from an exciplex, in general, the emission maximum wavelength thereof is observed as shifted on the longer wavelength side than the emission maximum wavelength of the emission spectrum of a single film.

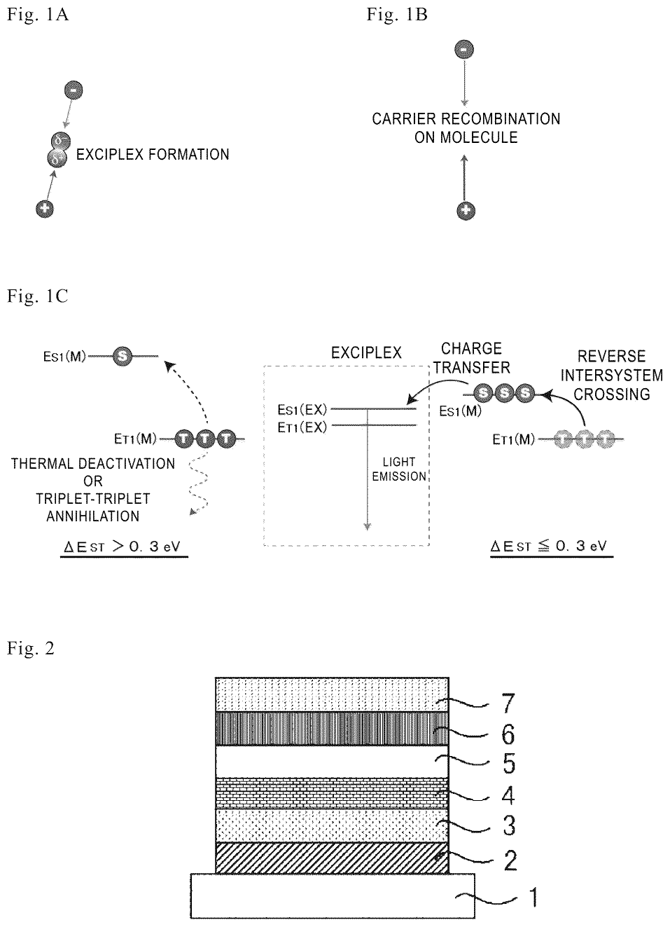

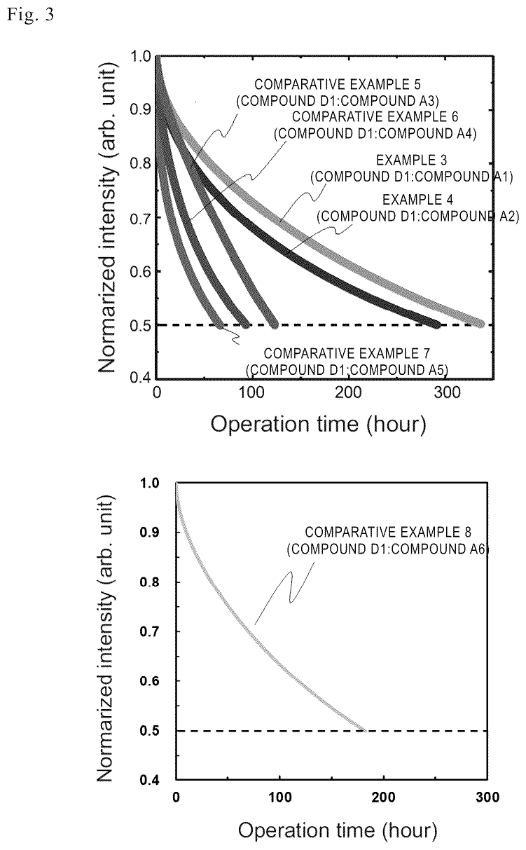

The composition of the present invention is a composition containing a donor compound and an acceptor compound to form an exciplex and satisfying the above-mentioned requirement A and requirement B1, and therefore can maintain stable light emission by forming an exciplex. This is assumed to be because, in the composition satisfying the requirement A and the requirement B1, the excited triplet energy formed by unnecessary injection of the carriers accumulated along with continuous carrier injection (continuous driving) into the acceptor compound or by unnecessary injection thereof into the donor compound can be utilized for exciplex formation. Here, “unnecessary carrier injection” means injection of holes into HOMO (highest occupied molecular orbital) of an acceptor compound that forms an excited complex, or injection of electrons into LUMO (lowest unoccupied molecular orbital) of a donor compound that forms an excited complex. A concrete mechanism thereof is described with reference to FIG. 1 as an example where ΔE_{ST} of an acceptor compound is 0.35 eV or less (in the case where an acceptor compound satisfies the requirement A).

Specifically, when a carrier is injected into the composition of the present invention, the donor compound or the acceptor compound is excited and the electron in HOMO of the donor compound moves to LUMO of the acceptor compound to form an exciplex (see FIG. 1A). By radiation deactivation from the lowest excited singlet energy level E_{T1}(EX) of the exciplex, fluorescence is emitted. In addition, in the exciplex, the energy difference ΔE_{ST} between the lowest excited single energy level E_{S1}(EX) and the lowest excited triplet energy level E_{T1}(EX) is extremely small, therefore readily causing reverse intersystem crossing from the excited triplet state to the excited singlet state, and accordingly the excited singlet state formed by the reverse intersystem crossing also undergoes radiation deactivation to emit delayed fluorescence. Therefore, in the exciplex, the excited triplet energy is also effectively utilized for light emission along with the excited singlet energy to attain a high emission efficiency.

However, when holes accumulate in a high density along with continuous driving, unnecessary hole injection occurs from HOMO of the donor compound to HOMO of the acceptor compound. As a result, as shown in FIG. 1B, holes and electrons recombine on the acceptor compound to cause a phenomenon that the acceptor compound itself also transitions to an excited singlet state and an excited triplet state.

At that time, as shown on the left side of FIG. 1C, when ΔE_{ST} of the acceptor compound is more than 0.35 eV (when the requirement A in the present invention is not satisfied), thermal deactivation may occur before radiation deactivation or high-density accumulation may occur to cause triplet-triplet annihilation since the excited triplet state has a long lifetime, therefore failing in in effective utilization for light emission. Consequently, in a system not satisfying the requirement A, light emission intensity rapidly lowers in prolongation of a driving time, and therefore the driving lifetime of the system shortens.

On the other hand, as shown on the right side of FIG. 1C, in the case where ΔE_{ST} of the acceptor compound is 0.35 eV or less (in the case where the requirement A in the present invention is satisfied), reverse intersystem crossing from the excited triplet state to the excited single state readily occurs, since the difference between the lowest excited singlet energy level E_{S1}(M) and the lowest excited triplet energy level E_{T1}(M) thereof is small. Consequently, even when the acceptor compound itself transitions to an excited triplet state owing to unnecessary hole injection thereinto, the compound can be efficiently transferred to an excited single state via reverse intersystem crossing. With that, the lowest excited singlet energy level E_{S1}(EX) of the exciplex is generally lower than the lowest excited singlet energy level E_{S1}(M) of the acceptor compound, and therefore the excited singlet energy generated in the acceptor compound transfers to a lowest excited singlet energy level E_{S1}(EX) along with charge transfer to contribute toward exciplex formation. Namely, when the acceptor compound satisfies the requirement A, the energy can be effectively utilized for exciplex formation without causing high-density accumulation of the excited triplet energy generated by unnecessary hole injection into the acceptor compound.

Further, in the composition of the present invention, where the lowest excited triplet energy level E_{T1}(M) of the acceptor compound having ΔE_{ST} of 0.35 eV or less falls within a range of E_{T1}(EX)−0.2 to E_{T1}(EX)eV, namely, where the requirement B1 in the present invention is satisfied, the excited triplet energy of the exciplex can be efficiently transferred to the acceptor compound to suppress accumulation of triplet excitons on the exciplex. In addition, the excited triplet energy transferred from the exciplex can be efficiently converted into excited singlet energy on the acceptor compound by a route via the above-mentioned reverse intersystem crossing for reuse for exciplex formation.

From this, the composition of the present invention satisfying the requirement A and the requirement B1 can stably maintain light emission by exciplex and can realize a long driving lifetime.

Here, in the above description, the light emission mechanism of the composition of the present invention is explained with reference to a case, as an example, where the acceptor compound satisfies the requirement A, but the same may apply also to a case where the donor compound satisfies the requirement A, except that the lowest excited singlet energy level and the lowest excited triplet energy level of the donor compound correspond to E_{S1}(M) and E_{T1}(M), respectively, and according to the same mechanism as above, stable light emission by exciplex and a long driving lifetime can also be realized.

In any case, the lower limit of E_{T1}(M) in the requirement B1 is preferably E_{T1}(EX)−0.2, more preferably E_{T1}(EX)−0.1. With that, reverse intersystem crossing efficiency on each compound can be higher.

In the following, the donor compound and the acceptor compound that the composition of the invention contains, and other optional components that may be in the composition are described.

### [Acceptor Compound]

The acceptor compound is a compound having an electron-receiving unit that receives electrons injected into the compound, and preferably has group having a negative Hammett's σp value.

Here, “Hammett's σp value” is one propounded by L. P. Hammett, and is to quantify the influence of a substituent on the reaction rate or the equilibrium of a para-substituted benzene derivative. Specifically, this is a constant (σp value) specific to the substituent in the following expression:

log(k/k₀)=ρσp

or

log(K/K₀)=ρσp,

which is established between the substituent in a para-substituted benzene derivative and the reaction rate constant or the equilibrium constant thereof. In the above expressions, k represents a rate constant of a benzene derivative not having a substituent, k₀ represents a rate constant of a benzene derivative substituted with a substituent, K represents an equilibrium constant of a benzene derivative not having a substituent, K₀ represents an equilibrium constant of a benzene derivative substituted with a substituent, and ρ represents a reaction constant determined by the kind and the condition of reaction. Regarding the description relating to the “Hammett's σp value” in the present invention and the numerical value of each substituent, reference may be made to the description relating to the op value in Hansch, C. et. al., Chem. Rev., 91, 165-195 (1991). A substituent having a negative Hammett's σp value tends to show an electron donating performance (donor performance), and a substituent having a positive Hammett's σp value tends to show an electron accepting performance (acceptor performance).

The acceptor compound has a group having a negative Hammett's σp value, and therefore when holes are injected into the acceptor compound from HOMO of a donor compound in continuous driving, the group having a negative Hammett's σp value functions as a hole accepting unit (HOMO) that receives the holes to thereby prevent injection of holes into HOMO of an electron accepting unit. Accordingly, decomposition of the acceptor compound molecules to be caused by injection of holes into HOMO of the electron accepting unit can be prevented, and the stability of exciplexes in continuous driving can be improved more. In addition, when a group having a negative Hammett's σp value is introduced into the acceptor compound, an electron state where HOMO and LOMO are spatially separated from each other can be formed to readily attain a small ΔE_{ST}.

The acceptor compound preferably has a heteroaromatic ring containing a nitrogen atom as a ring skeleton constituting atom, and a substituted or unsubstituted diarylamino group. The heteroaromatic ring can be constituted as an electron accepting unit, and the substituted or unsubstituted diarylamino group can be constituted as a group having a negative Hammett's σp value. In the acceptor compound, the number per molecule of the the heteroaromatic rings each containing a nitrogen atom as a ring skeleton-constituting atom may be one or two or more. When the acceptor compound has two or more heteroaromatic ring each containing a nitrogen atom as a ring skeleton-constituting atom, the plural heteroaromatic ring may be the same as or different from each other. In the acceptor compound, the number per molecule of the substituted or unsubstituted diarylamino groups may be one or two or more. When the acceptor compound has two or more substituted or unsubstituted diarylamino groups, the plural substituted or unsubstituted diarylamino groups may be the same as or different from each other.

The heteroaromatic ring containing a nitrogen atom as a ring skeleton-constituting atom may be a monocyclic ring or may also be a condensed ring formed by condensation of two or more heteroaromatic rings each having a nitrogen atom, or a condensed ring formed by condensation of at least one heteroaromatic ring having a nitrogen atom and at least one aromatic ring. The heteroaromatic ring preferably contains a 6-membered ring having a nitrogen atom as a ring skeleton-constituting atom, and the number of the nitrogen atoms in the 6-membered ring is preferably 1 to 3. Specific examples of the 6-membered ring having a nitrogen atom as a ring skeleton-constituting atom include a pyridine ring, a pyrazine ring, a pyrimidine ring, a pyridazine ring, and a triazine ring.

Regarding the description of the “substituted or unsubstituted aryl group” in the substituted or unsubstituted diarylamino group, reference may be made to the description of the “substituted or unsubstituted aryl group” in R⁶ and R⁷ in the following formula (2). The two aryl groups of the diarylamino group may bond to each other via a single bond or a linking group (first linking group) to form a heterocyclic structure. Regarding the preferred range and specific examples of the first linking group, reference may be made to the description of the linking group that links the aryl group in R⁶ and the aryl group in R⁷ in the following formula (2).

The heteroaromatic ring containing a nitrogen atom as a ring skeleton-constituting atom and the substituted or unsubstituted diarylamino group may bond via a single bond, or via a linking group (second linking group). Regarding the description of the second linking group, reference may be made to the description of the “substituted or unsubstituted arylene group” in L¹ in the following formula (2). The number of the substituted or unsubstituted diarylamino groups bonding to the second linking group may be one or may be two or more. In the case where two or more substituted or unsubstituted diarylamino groups bond to the second linking group, the plural substituted or unsubstituted diarylamino groups may be the same as or different from each other.

Preferred examples of the acceptor compound include compounds having a structure represented by the following formula (1).

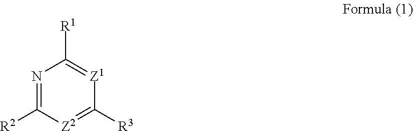

In the formula (1), Z¹ represents N or C(R⁴), Z² represents N or C(R⁵), R¹ to R⁵ each independently represent a hydrogen atom, CN, a substituted or unsubstituted alkyl group, a substituted or unsubstituted aryl group, or a substituted or unsubstituted heteroaryl group, but at least one of R¹ to R⁵ is a group having a substituted or unsubstituted diarylamino group. R¹ to R⁵ may be the same as or different from each other.

In the formula (1), any one of Z¹ and Z² may be N and the other may be C(R⁴) or C(R⁵), or both may be N. Preferred is a triazine ring where both Z¹ and Z² are N.

The alkyl group in R¹ to R⁵ may be linear, branched or cyclic. The carbon number thereof is preferably 1 to 20, more preferably 1 to 10, even more preferably 1 to 6. Examples of the group include a methyl group, an ethyl group, an n-propyl group, and an isopropyl group. The substituent with which the alkyl group can be substituted includes an aryl group having 6 to 40 carbon atoms, a heteroaryl group having 3 to 40 carbon atoms, an alkenyl group having 2 to 10 carbon atoms, and an alkynyl group having 2 to 10 carbon atoms. These substituents may be further substituted with a substituent.

The aromatic ring that constitutes the aryl group in of R¹ to R⁵ may be a monocyclic ring or a condensed ring formed by condensation of two or more aromatic rings, or may also be a linked ring formed by linking of two or more aromatic rings. In the case where two or more aromatic rings are linked, they may be linked linearly or may be linked in a branched manner. The carbon number of the aromatic ring that constitutes the aryl group is preferably 6 to 40, more preferably 6 to 22, even more preferably 6 to 18, further more preferably 6 to 14, especially more preferably 6 to 10. Specific examples of the aryl group include a phenyl group, a naphthalenyl group, and a biphenyl group.

The heteroaromatic ring to constitute the heteroaryl group in R¹ to R⁵ may be a monocyclic ring or may also be a condensed ring formed by condensation of one or more hetero rings and one or more aromatic rings or hetero rings, or may be a linking group formed by linking of one or more hetero rings and one or more aromatic rings or hetero rings. The carbon number of the hetero ring to constitute the heteroaryl group is preferably 3 to 40, more preferably 5 to 22, even more preferably 5 to 18, further more preferably 5 to 14, especially more preferably 5 to 10. The hetero atom to constitute the hetero ring is preferably a nitrogen atom. Specific examples of the hetero ring include a pyridine ring, a pyridazine ring, a pyrimidine ring, a triazole ring, and a benzotriazole ring.

The substituent that can be introduced into the aryl group and the heteroaryl group in R¹ to R⁵ includes a halogen atom, a cyano group, an alkyl group having 1 to 20 carbon atoms, an aryl group having 6 to 40 carbon atoms, a heteroaryl group having 3 to 40 carbon atoms, an alkenyl group having 2 to 10 carbon atoms, and an alkynyl group having 2 to 10 carbon atoms. Among these substituents, those that can be substituted with a substituent can be substituted.

At least one of R¹ to R⁵ is a group having a substituted or unsubstituted diarylamino group. Among R¹ to R⁵, the number of the groups having a substituted or unsubstituted diarylamino group may be one or may be two or more. In the case where two or more of R¹ to R⁵ are groups having a substituted or unsubstituted diarylamino group, these substituted or unsubstituted diarylamino group-having groups may be the same as or different from each other.

The group having a substituted or unsubstituted diarylamino group may be a substituted or unsubstituted diarylamino group, or may also be a group that has a linking group to link a substituted or unsubstituted diarylamino group to the heteroaromatic ring of the formula (1). Regarding the description of the substituted or unsubstituted diarylamino group, reference may be made to the description of the “substituted or unsubstituted diarylamino group” that constitutes the acceptor compound along with the above-mentioned heteroaromatic ring, and regarding the description of the linking group, reference may be made to the description of the “second linking group” that links the substituted or unsubstituted diarylamino group to the heteroaromatic ring.

Examples of the group having a substituted or unsubstituted diarylamino group that at least one of R¹ to R⁵ represents include groups represented by the following formula (2).

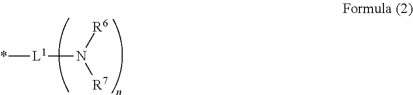

In the formula (2), R⁶ and R⁷ each independently represent a substituted or unsubstituted aryl group, L¹ represents a single bond, or a substituted or unsubstituted arylene group. n represents an integer of 1 or more and not more than the maximum number which can be substituted for L¹, * indicates the position bonding to the heteroaromatic ring in the formula (1). R⁶ and R⁷ may be the same as or different from each other.

Regarding the description and the preferred range of the aromatic ring to constitute the aryl group in R⁶ and R⁷, and the aromatic ring to constitute the arylene group in L¹, reference may be made to the description and the preferred range of the aromatic ring to constitute the aryl group in the above R¹ to R⁵, and regarding the specific examples of the aryl group in R⁶ and R⁷, reference may be made to the specific examples of the aryl group in the above R¹ to R⁵. Specific examples of the arylene group in L¹ include a phenylene group, a naphthalenediyl group, and a biphenyldiyl group, and preferred is a phenylene group. The phenylene group may be any of a 1,2-phenylene group, a 1,3-phenylene group, and a 1,4-phenylene group, but is preferably a 1,4-phenylene group. Regarding the description and the preferred range of the substituent that can be introduced into the aryl group and the arylene group, reference may be made to the description and the preferred range of the substituent that R¹¹ to R²⁰ in the following formula (2a) can have.

The aryl group in R⁶ and the aryl group in R⁷ may bond to each other via a single bond or a linking group to form a heterocyclic structure. The linking group is preferably a linking group that has a linking chain length of one atom. Specific examples of the linking group include linking groups represented by —O—, —S—, —N(R⁹¹)— or —C(R⁹²)(R⁹³)—. Here, R⁹¹ to R⁹³ each independently represent a hydrogen atom or a substituent. Examples of the substituent that R⁹¹ can have include an alkyl group having 1 to 20 carbon atoms, an aryl group having 6 to 40 carbon atoms, and a heteroaryl group having 3 to 40 carbon atoms. As examples thereof, the substituent that R⁹² and R⁹³ can have each are independently a hydroxy group, a halogen atom, an alkyl group having 1 to 20 carbon atoms, an alkoxy group having 1 to 20 carbon atoms, an alkylthio group having 1 to 20 carbon atoms, an alkyl-substituted amino group having 1 to 20 carbon atoms, an aryl-substituted amino group having 12 to 40 carbon atoms, an aryl group having 6 to 40 carbon atoms, a heteroaryl group having 3 to 40 carbon atoms, an alkenyl group having 2 to 10 carbon atoms, an alkynyl group having 2 to 10 carbon atoms, an alkylamide group having 2 to 20 carbon atoms, an arylamide group having 7 to 21 carbon atoms, a trialkylsilyl group having 3 to 20 carbon atoms.

n is preferably an integer of 1 to 5, more preferably an integer of 1 to 3, even more preferably an integer of 1 to 2.

The group parenthesized with n in the formula (2) (substituted or unsubstituted diarylamino group) is preferably a group represented by the formula (2a).

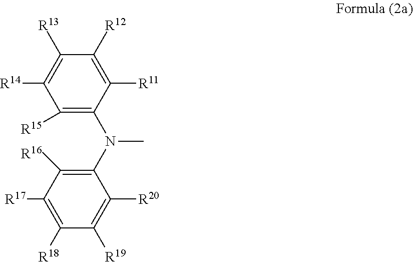

In the formula (2a), R¹¹ to R²⁰ each independently represent a hydrogen atom or a substituent. The number of the substituents is not specifically limited, and all R¹¹ to R²⁰ may be unsubstituted, (that is, all hydrogen atoms). In the case where two or more of R¹¹ to R²⁰ are substituents, the plural substituents may be the same as or different from each other. In the case where the formula (2a) has a substituent, the substituent is preferably at least one of R¹² to R¹⁴, and R¹⁷ to R¹⁹, more preferably at least one of R¹³ and R¹⁶.

Examples of the substituent that R¹¹ to R²⁰ may have include a hydroxy group, a halogen atom, a cyano group, an alkyl group having 1 to 20 carbon atoms, an alkoxy group having 1 to 20 carbon atoms, an alkylthio group having 1 to 20 carbon atoms, an alkyl-substituted amino group having 1 to 20 carbon atoms, an acyl group having 2 to 20 carbon atoms, an aryl group having 6 to 40 carbon atoms, a heteroaryl group having 3 to 40 carbon atoms, an alkenyl group having 2 to 10 carbon atoms, an alkynyl group having 2 to 10 carbon atoms, an alkoxycarbonyl group having 2 to 10 carbon atoms, an alkylsulfonyl group having 1 to 10 carbon atoms, a haloalkyl group having 1 to 10 carbon atoms, an amide group, an alkylamide group having 2 to 10 carbon atoms, a trialkylsilyl group having 3 to 20 carbon atoms, a trialkylsilylalkyl group having 4 to 20 carbon atoms, a trialkylsilylalkenyl group having 5 to 20 carbon atoms, a trialkylsilylalkynyl group having 5 to 20 carbon atoms, and a nitro group. Among these specific groups, those that can be further substituted with a substituent can be substituted. More preferred substituents are a halogen atom, a cyano group, a substituted or unsubstituted alkyl group having 1 to 20 carbon atoms, an alkoxy group having 1 to 20 carbon atoms, a substituted or unsubstituted aryl group having 6 to 40 carbon atoms, a substituted or unsubstituted heteroaryl group having 3 to 40 carbon atoms, and a dialkyl-substituted amino group having 1 to 20 carbon atoms. More preferred substituents are a fluorine atom, a chlorine atom, a cyano group, a substituted or unsubstituted alkyl group having 1 to 10 carbon atoms, a substituted or unsubstituted alkoxy group having 1 to 10 carbon atoms, a substituted or unsubstituted aryl group having 6 to 15 carbon atoms, and a substituted or unsubstituted heteroaryl group having 3 to 12 carbon atoms. For the substituent in R¹¹ to R²⁰, also preferred is a group represented by the formula (2a).

R¹¹ and R¹², R¹² and R¹³, R¹³ and R¹⁴, R¹⁴ and R¹⁵, R¹⁵ and R¹⁶, R¹⁶ and R¹⁷, R¹⁷ and R¹⁸, R¹⁸ and R¹⁹, and R¹⁹ and R²⁰ each can bond to each other to form a cyclic structure. The cyclic structure may be an aromatic ring or an aliphatic ring, or may contain a hetero atom, and may be further a condensed ring of two or more rings. The hetero atom as referred to herein is preferably selected from the group consisting of a nitrogen atom, an oxygen atom and a sulfur atom. Examples of the cyclic structure to be formed include a benzene ring, a naphthalene ring, a pyridine ring, a pyridazine ring, a pyrimidine ring, a pyrazine ring, a pyrrole ring, an imidazole ring, a pyrazole ring, a triazole ring, an imidazoline ring, an oxazole ring, an isoxazole ring, a thiazole ring, an isothiazole ring, a cyclohexadiene ring, a cyclohexene ring, a cyclopentaene ring, a cycloheptatriene ring, a cycloheptadiene ring, and a cycloheptaene ring.

The group represented by the formula (2a) is preferably a group represented by any of the following formulae (2b) to (2f), more preferably a group represented by the formula (2b).

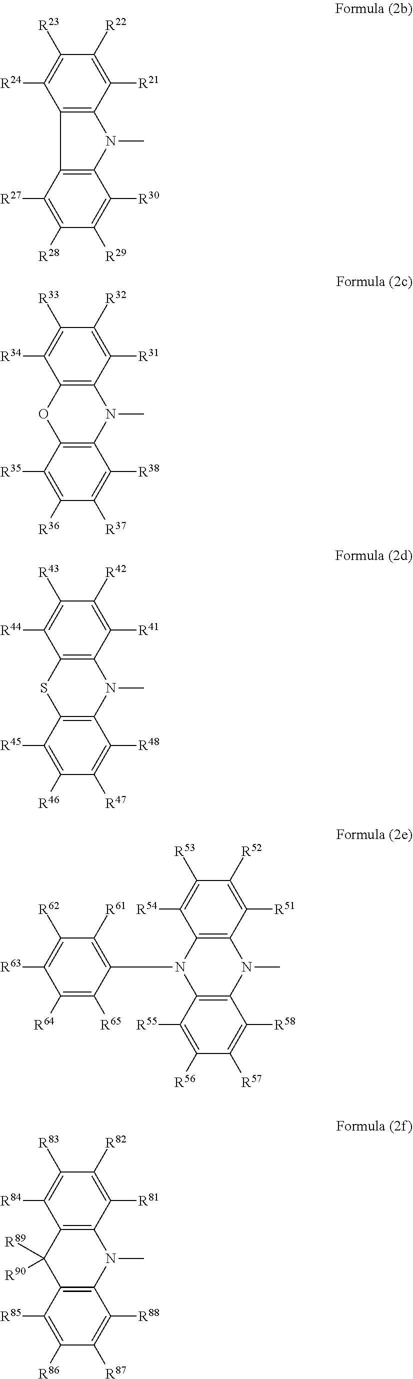

In the formulae (2b) to (2f), R²¹ to R²⁴, R²⁷ to R³⁸, R⁴¹ to R⁴⁸, R⁵¹ to R⁵⁸, R⁶¹ to R⁶⁵, and R⁸¹ to R⁹⁰ each independently represent a hydrogen atom or a substituent. Regarding the description and the preferred range of the substituent as referred to herein, reference may be made to the description and the preferred range of the substituent that the above-mentioned R¹¹ to R²⁰ can have. The number of the substituents in the formulae (2b) to (2f) is not specifically limited. Preferably, R²¹ to R²⁴, R²⁷ to R³⁸, R⁴¹ to R⁴⁸, R⁵¹ to R⁵⁸, R⁶¹ to R⁶⁵, and R⁸¹ to R⁹⁰ each are independently a group represented by any of the above formulae (2b) to (2f). Also preferably, these are all unsubstituted (that is, all hydrogen atoms). In the case where the formulae (2b) to (2f) each have two or more substituents, these substituents may be the same as or different from each other.

In the case where the formulae (2b) to (2f) have a substituent, the substituent in the formula (2b) is preferably any of R²² to R²⁴, and R²⁷ to R²⁹, more preferably at least one of R²³ and R²⁸. The substituent in the formula (2c) is preferably any of R³² to R³⁷. In the formula (2d), preferred is any of R⁴² to R⁴⁷, in the formula (2e), preferred is any of R⁵², R⁵³, R⁵⁶, R⁵⁷, and R⁶² to R⁶⁴, and in the formula (2f), preferred is any of R⁸² to R⁸⁷, R⁸⁹, and R⁹⁰, and more preferred are R⁸⁹ and R⁹⁰. The substituent that R⁸⁹ and R⁹⁰ represent is preferably a substituted or unsubstituted aryl group having 6 to 40 carbon atoms, more preferably a substituted or unsubstituted phenyl group. Preferably, the substituent that R⁸⁹ and R⁹⁰ represent is the same.

In the formulae (2b) to (2f), R²¹ and R²², R²² and R²³, R²³ and R²⁴, R²⁷ and R²⁸, R²⁸ and R²⁹, R²⁹ and R³⁰, R³¹ and R³², R³² and R³³, R³³ and R³⁴, R³⁵ and R³⁶, R³⁶ and R³⁷, R³⁷ and R³⁸, R⁴¹ and R⁴², R⁴² and R⁴³, R⁴³ and R⁴⁴, R⁴⁵ and R⁴⁶, R⁴⁶ and R⁴⁷, R⁴⁷ and R⁴⁸, R⁵¹ and R⁵², R⁵² and R⁵³, R⁵³ and R⁵⁴, R⁵⁵ and R⁵⁶, R⁵⁶ and R⁵⁷, R⁵⁷ and R⁵⁸, R⁶¹ and R⁶², R⁶² and R⁶³, R⁶³ and R⁶⁴, R⁶⁴ and R⁶⁵, R⁵⁴ and R⁶¹, R⁵⁵ and R⁶⁵, R⁸¹ and R⁸², R⁸² and R⁸³, R⁸³ and R⁸⁴, R⁸⁵ and R⁸⁶, R⁸⁶ and R⁸⁷, R⁸⁷ and R⁸⁸, and R⁸⁹ and R⁹⁰ each may bond to each other to form a cyclic structure. Regarding the description and the preferred examples of the cyclic structure, reference may be made to the description and the preferred examples of the cyclic structure that R¹¹ and R¹² in the above formula (2a) form by bonding to each other.

Preferably, all the groups represented by the formula (2a) existing in the formula (1) are groups represented by any one of the formulae (2b) to (2f). As one preferred example, all the groups are represented by the formula (2b).

Preferably, the acceptor compound has two or more, more preferably three or more substituted or unsubstituted diarylamino groups in the molecule. The upper limit of the number of the substituted or unsubstituted diarylamino groups in the molecule is not specifically limited and may be 6 or less, or may be 5 or less, or may also be 4.

In preferred examples of the compound represented by the formula (1), one of R¹ to R³ is a group having a substituted or unsubstituted diarylamino group. In these cases, the remaining R¹ to R³ each may be a hydrogen atom or a substituent, but is preferably a substituent, more preferably a substituted or unsubstituted aryl group.

In the following, specific examples of the compound represented by the formula (1) are shown. However, the compound represented by the formula (1) which can be used in the present invention should not be limitatively interpreted by these examples.

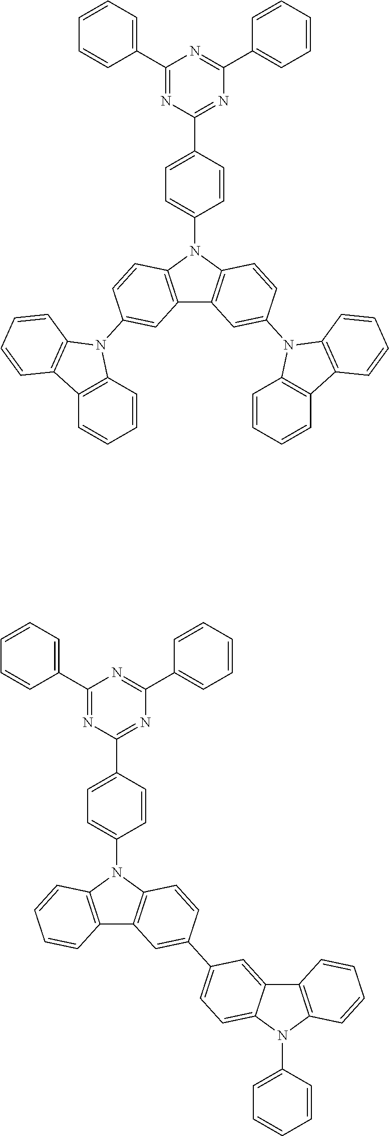 [SMILES: c1ccc(-c2nc(-c3ccccc3)nc(-c3ccc(-n4c5ccc(-n6c7ccccc7c7ccccc76)cc5c5cc(-n6c7ccccc7c7ccccc76)ccc54)cc3)n2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1]

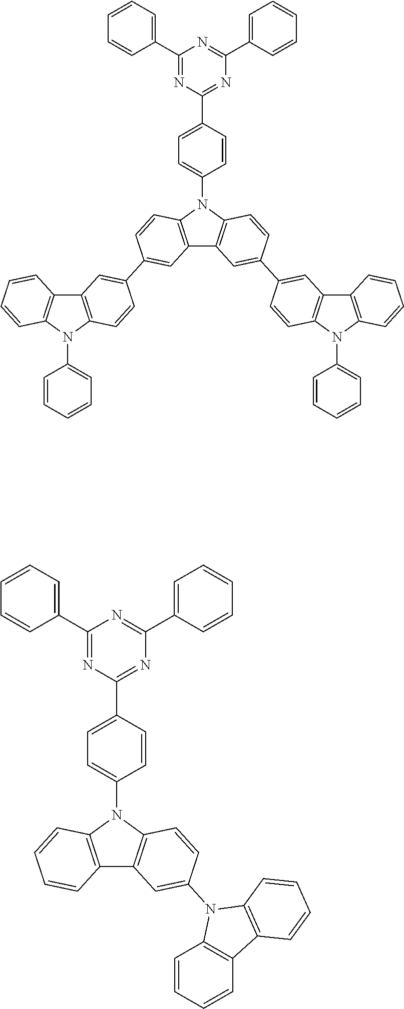 [SMILES: c1ccc(-c2nc(-c3ccccc3)nc(-c3ccc(-n4c5ccc(-c6ccc7c(c6)c6ccccc6n7-c6ccccc6)cc5c5cc(-c6ccc7c(c6)c6ccccc6n7-c6ccccc6)ccc54)cc3)n2)cc1 ; c1ccc(-c2nc(-c3ccccc3)nc(-c3ccc(-n4c5ccccc5c5cc(-n6c7ccccc7c7ccccc76)ccc54)cc3)n2)cc1]

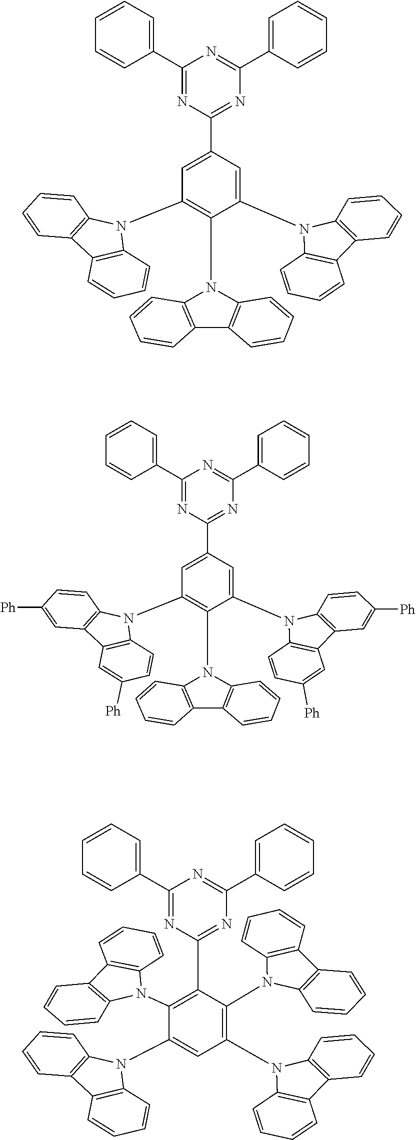 [SMILES: c1ccc(-c2nc(-c3ccccc3)nc(-c3cc(-n4c5ccccc5c5ccccc54)c(-n4c5ccccc5c5ccccc54)c(-n4c5ccccc5c5ccccc54)c3)n2)cc1 ; c1ccc(-c2ccc3c(c2)c2cc(-c4ccccc4)ccc2n3-c2cc(-c3nc(-c4ccccc4)nc(-c4ccccc4)n3)cc(-n3c4ccc(-c5ccccc5)cc4c4cc(-c5ccccc5)ccc43)c2-n2c3ccccc3c3ccccc32)cc1 ; c1ccc(-c2nc(-c3ccccc3)nc(-c3c(-n4c5ccccc5c5ccccc54)c(-n4c5ccccc5c5ccccc54)cc(-n4c5ccccc5c5ccccc54)c3-n3c4ccccc4c4ccccc43)n2)cc1]

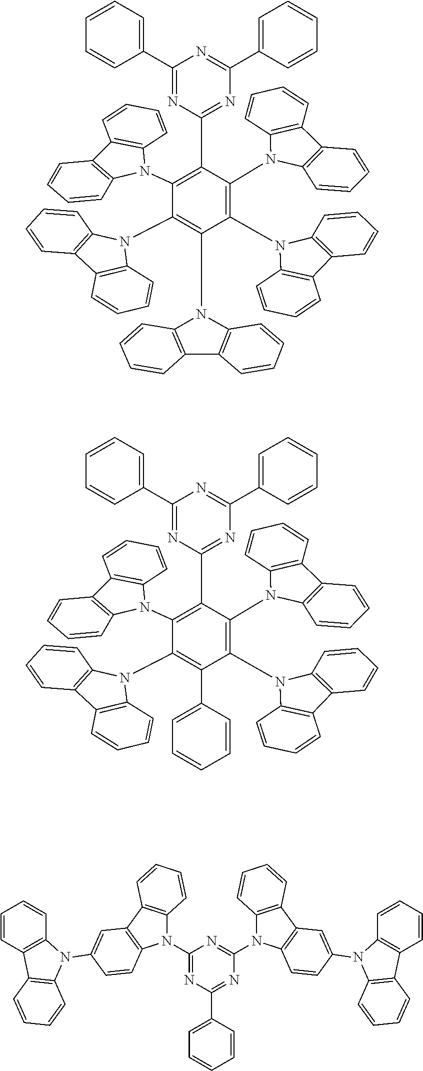

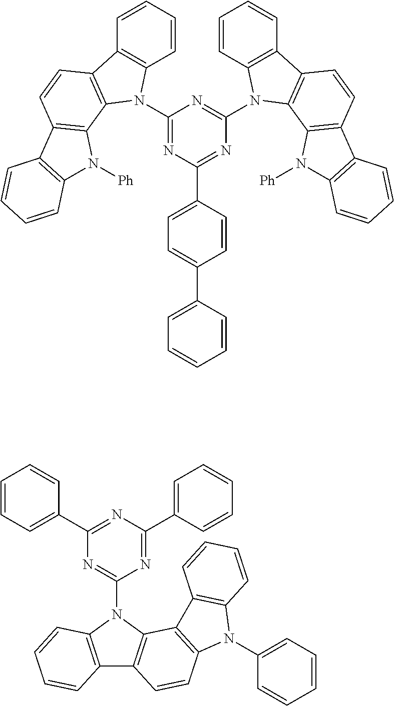 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-n3c4ccccc4c4ccc5c(c6ccccc6n5-c5ccccc5)c43)n2)cc1]

### [Donor Compound]

The donor compound is a compound having an electron accepting unit that receives holes injected into the composition. Preferably, the donor compound does not have a group having a Hammett's σp value of 0.2 or more, more preferably does not have a group having a positive Hammett's σp value.

Preferably, the donor compound has two or more triarylamine partial structures. The plural triarylamine partial structures that the donor compound has may be the same as or different from each other. The three aryl groups bonding to the nitrogen atom of the triarylamine structure may be the same as or different from each other. Regarding the description and the preferred range of the aromatic ring that constitutes the aryl group, and the specific examples of the aryl group, reference may be made to the description and the preferred range of the aromatic ring that constitutes the aryl group in the above R¹ to R⁵ and the specific examples of the aryl groups therein. Each aryl group of the triarylamine partial structure may be substituted with a substituent. Regarding the description and the preferred range of the substituent that the aryl group may have, reference may be made to the description and the preferred range of the substituent that the above R¹¹ to R²⁰ may have. At least one combination of the neighboring aryl groups in the triarylamine structure may bond via a single bond or a linking group. Regarding the description, the preferred range and the specific examples of the linking group, reference may be made to the description of the linking group that links the aryl group in the above R⁶ and the aryl group in R⁷.

The number of the triarylamine partial structures that the donor compound has is preferably 2 to 6, more preferably 2 to 4, even more preferably 2 or 3.

Preferred examples of the donor compound are compounds having a structure represented by the following formula (3).

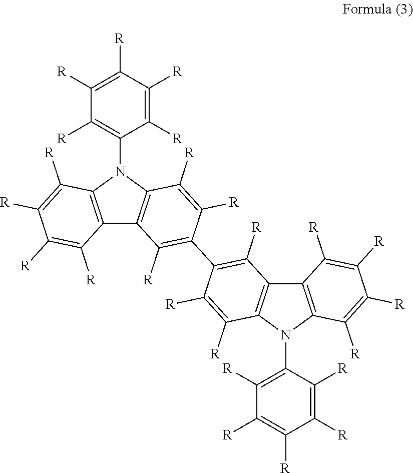

In the formula (3), R each independently represents a hydrogen atom or a substituent. Plural R's may be the same as or different from each other. The number of the substituents of plural R's is not specifically limited, and all may be unsubstituted (all hydrogen atoms). In the case where a substituent exists in plural R's, preferably, at least R in the 3-position of the carbazole ring is a substituent.

Regarding the description and the preferred range of the substituent that R may have, reference may be made to the description and the preferred range of the substituent that the above R¹¹ to R²⁰ may have. Preferably, at least one of plural R's in the formula (3) is a substituted or unsubstituted carbazolyl group, more preferably a substituted or unsubstituted 3-carbazolyl group, even more preferably a 3-carbazolyl group substituted with a substituent at the 9-position, further more preferably a 3-carbazolyl group substituted with a substituted or unsubstituted aryl group at the 9-position.

In the following, a specific example of the compound represented by the formula (3) is shown. However, the compound represented by the formula (3) that can be used in the present invention should not be limitatively interpreted by the example.

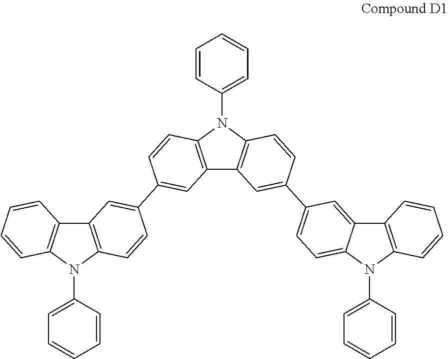 [SMILES: c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1]

### [Proportion of Donor Compound and Acceptor Compound]

The proportion of the acceptor compound in the composition may be 1% by mass or more, relative to the total mass of the acceptor compound and the donor compound therein, or may be 10% by mass or more, or may also be 50% by mass or more. Also in the composition, the proportion of the acceptor compound may be 99% by mass or less, relative to the total mass of the acceptor compound and the donor compound therein, or may be 50% by mass or less, or may also be 10% by mass or less.

### [Other Components]

The composition of the present invention may optionally contain any other components, along with the donor compound and the acceptor compound. Preferred examples of the other components include a fluorescent compound, a host material, a phosphorescent compound, and a quantum dot.

### (Fluorescent Compound)

The “fluorescent compound” in the present specification means a compound capable of emitting fluorescence by radiation deactivation from an excited singlet state, and the light emission may include delayed fluorescence. Delayed fluorescence is a light that is emitted from the excited singlet state formed via reverse intersystem crossing, and is observed later than the light (instantaneous fluorescence) from the excited singlet state formed by direct transition.

When the composition of the present invention contains a fluorescent compound, the excited singlet energy of the exciplex can be transferred to the fluorescent compound to emit light. Preferably, the fluorescent compound is such that the photoabsorption band thereof overlaps with the emission peak of the exciplex. The emission wavelength of the fluorescent compound is not specifically limited, and may be, for example, in a visible light region or in a near-IR region. The visible light region may be any of a blue region, a green region or a red region.

In the composition containing a fluorescent compound, preferably, the lowest excited triplet energy level E_{T1}(F) of the fluorescent compound and the excited triplet energy level E_{T1}(M) of the donor compound or the acceptor compound satisfying the requirement A satisfy the following relational expression.

E_{T1}(M)≤E_{T1}(F)

A fluorescent compound, especially a blue fluorescent compound having a high E_{T1}(F) may cause unstable device operation owing to high-density accumulation of triplet excitons in continuous driving. As opposed to this, when the above relational expression is satisfied, energy can transfer from the lowest excited triplet energy level E_{T1}(F) of the fluorescent compound to the lowest excited triplet energy level E^{T1}(M) of the donor compound or the acceptor compound, and further through a series of paths of reverse intersystem crossing on the donor compound or the acceptor compound and exciplex formation by charge transfer in the excited singlet state formed by the reverse intersystem crossing, the number of the triplet excitons in the fluorescent compound reduces. Consequently, unstable operation to be caused by accumulation of triplet excitons of the fluorescent compound can be evaded, and a long driving lifetime can be thereby attained.

Further, when the following relational expression is satisfied, the lowest excited triplet energy level E_{T1}(M) of the donor compound or the acceptor compound can be closer to the lowest excited singlet energy level E_{S1}(M) thereof, and therefore reverse intersystem crossing can be efficiently attained on the donor compound or the acceptor compound.

E_{T1}(F)−0.2≤E_{T1}(M)≤E_{T1}(F)

Still further, in the composition containing a fluorescent compound, preferably, the lowest excited singlet energy level E_{S1}(EX) of the exciplex, the lowest excited singlet energy level E_{S1}(F) of the fluorescent compound, the energy Eₚₑₐₖ(EX) obtained from the maximum emission wavelength of the exciplex, and the energy Eₚₑₐₖ(F) obtained from the maximum emission wavelength of the fluorescent compound all satisfy the following relational expressions (unit eV).

E_{S1}(F)<E_{S1}(EX)

Eₚₑₐₖ(EX)<Eₚₑₐₖ(F)

With that, the excited singlet energy of the exciplex derived from the triplet exciton of the fluorescent compound can transfer from the lowest excited singlet energy level E_{S1}(EX) thereof to the lowest excited singlet energy level E_{S1}(F) of the fluorescent compound and can be reused for light emission of the fluorescent compound to more stabilize device operation.

The proportion of the fluorescent compound in the composition may be 0.5% by mass or more, relative to the total mass of the composition, or may be 1% by mass or more, or may also be 3% by mass or more. The proportion of the fluorescent compound in the composition may be 50% by mass or less, relative to the total mass of the composition, or may be 15% by mass or less, or may also be 5% by mass or less.

### [Form of Composition]

Not specifically limited, the form of the composition is preferably a filmy one. In the filmy composition, the donor compound and the acceptor compound can uniformly exist in the film, or the film may have a region where the donor compound exists in a high concentration and a region where the acceptor compound exists in a high concentration, or may have a multilayer configuration where one or more layers containing the donor compound and one or more layers containing the acceptor compound are laminated.

The filmy composition may be formed in a dry process such as a co-evaporation method, or may also be formed in a wet process using a coating liquid containing the donor compound and the acceptor compound.

The thickness of the filmy composition is preferably 5 to 100 nm, more preferably 10 to 500 nm, even more preferably 15 to 100 nm.

### <Composition (Second Composition)>

Next, the second composition of the present invention is described.

The second composition of the present invention contains a donor compound and an acceptor compound to form an exciplex, and satisfies the following requirement A and requirement B2.

### (Requirement A)

The donor compound or the acceptor compound is such that the difference between the lowest excited triplet energy level and the lowest excited singlet energy level thereof, ΔE_{ST} is 0.35 eV or less.

### (Requirement B2)

The phosphorescence emitted from the composition is a phosphorescence from the donor compound or the acceptor compound.

The second composition differs from the first composition in that the requirement B2 is defined in place of the requirement B1 in the first composition, and regarding the description of the constitution except the requirement B2 in the composition 2, reference may be made to the corresponding description in the section of <Composition (first composition)>.

In the requirement B2, the phosphorescence emitted from the composition is a phosphorescence from the donor compound or the acceptor compound, which can be confirmed by comparing the phosphorescence spectra of the composition, the donor compound and the acceptor compound with each other and followed by confirming that the phosphorescent spectrum of the composition and the phosphorescent spectrum of the donor compound or the acceptor compound have a common emission maximum wavelength.

The requirement B2 means that the excited triplet energy of the exciplex formed in the composition transfers to the donor compound or the acceptor compound. With that, accumulation of triplet excitons in the exciplex can be prevented. In addition, the excited triplet energy transferred from the exciplex can be efficiently converted into an excited singlet energy by the reverse intersystem crossing in the donor compound or the acceptor compound and transferred to an exciplex, and can be thus reused for exciplex emission.

From these, the second composition of the present invention satisfying the requirement A and the requirement B2 can stably maintain exciplex emission to realize a long driving lifetime.

<Measurement Methods for E_{S1}(M), E_{T1}(M), ΔE_{ST}, E_{S1}(EX), E_{T1}(EX)>

The lowest excited singlet energy level E_{S1}(M) and the lowest excited triplet energy level E_{T1}(M) of the donor compound or the acceptor compound for use in the present invention, the energy difference ΔE_{ST} between E_{S1}(M) and E_{T1}(M), as well as the lowest excited singlet energy level E_{S1}(EX) and the lowest excited triplet energy level E_{T1}(EX) of the exciplex are measured as follows. In the following description, the object targeted for measurement is a donor compound or an acceptor compound for E_{S1}(M) and E_{T1}(M), ΔE_{ST} and for E_{S1}(EX) and E_{T1}(EX), the object targeted for measurement is a composition containing 50% by mass of the donor compound and 50% by mass of the acceptor compound.

[1] E_{S1}(M) and E_{S1}(EX)

The object targeted for measurement is vapor-deposited on an Si substrate in a thickness of 100 nm to prepare a sample. At room temperature (300 K), a fluorescent spectrum of the sample with a 360-nm excitation light is measured. Here, the light emission from immediately after the incidence of the excitation light to 100 nanoseconds after the incidence of the excitation light is integrated to provide a fluorescent spectrum on a vertical axis as an emission intensity and a horizontal axis as a wavelength. A tangent line is drawn to the rising on the short wavelength side of the fluorescent spectrum, and the wavelength value λedge [nm] at the intersection of the tangent line and the horizontal axis is read. The wavelength value is converted into an energy value according to the following conversion expression to be the lowest excited singlet energy level E_{S1}(M) or E_{S1}(EX).

Conversion Expression: lowest excited singlet energy level [eV]=1239.85/λedge

For measurement of the fluorescent spectrum, for example, a nitrogen laser (by Lasertechnik Berlin, MNL200) can be used for an excitation light source, and a streak camera (by Hamamatsu Photonics, C4334) can be used for a detector.

[2] E_{T1}(M) and E_{T1}(EX)

The same sample as that used for the measurement of the lowest excited singlet energy level is cooled to 30 K, the sample is irradiated with a 360-nm excitation light, and using a streak camera, the phosphorescence intensity is measured. The light emission from 1 millisecond after incidence of the excitation light to 20 milliseconds after the incidence is integrated to provide a phosphorescent spectrum on a vertical axis as an emission intensity and a horizontal axis as a wavelength. A tangent line is drawn to the rising on the short wavelength side of the phosphorescent spectrum, and the wavelength value λedge [nm] at the intersection of the tangent line and the horizontal axis is read. The wavelength value is converted into an energy value according to the following conversion expression to be the lowest excited triplet energy level E_{T1}(M) or E_{T1}(EX).

Conversion Expression: lowest excited triplet energy level [eV]=1239.85/λedge

The tangent line to the rising of the phosphorescent spectrum on the short wavelength side is drawn as follows. While moving on the spectral curve from the short wavelength side of the phosphorescent spectrum toward the maximum value on the shortest wavelength side among the maximum values of the spectrum, a tangent line at each point on the curve toward the long wavelength side is taken into consideration. With rising thereof (that is, with increase in the vertical axis), the inclination of the tangent line increases. The tangent line drawn at the point at which the inclination value has a maximum value is referred to as the tangent line to the rising on the short wavelength side of the phosphorescent spectrum.

The maximum point having a peak intensity of 10% or less of the maximum peak intensity of the spectrum is not included in the maximum value on the above-mentioned shortest wavelength side, and the tangent line drawn at the point which is closest to the maximum value on the shortest wavelength side and at which the inclination value has a maximum value is referred to as the tangent line to the rising on the short wavelength side of the phosphorescent spectrum.

### (3) ΔE_{ST}

Using E_{S1}(M) measured in [1] and E_{T1}(M) measured in [2], a value calculated by E_{S1}(M)-E_{T1}(M) is referred to as ΔE_{ST}.

### <Organic Light-Emitting Device>

The composition of the present invention emits light through exciplex formation and therefore secures a high emission efficiency, and in addition, since the composition can stably maintain the light emission by exciplex, it is useful as a material for a light-emitting layer in an organic light-emitting device. Regarding the mechanism that the composition of the present invention exhibits stable exciplex emission, reference may be made to the description in the section of <Composition (first composition)>. The composition of the present invention secures a high emission efficiency, and this is presumed to be because since ΔE_{ST} of the exciplex is small, reverse intersystem crossing from the excited triplet state to the excited singlet state can occur efficiently. The principle is described with reference to an organic electroluminescent device as one example.

In an organic electroluminescent device, carriers are injected to the light-emitting material from both the positive and negative electrodes to form an excited light-emitting material, and the thus-excited light-emitting material emits light. In general, in the case of a carrier-injection-type organic electroluminescent device, among the formed excitons, 25% are excited to an excited singlet state, and the remaining 75% are excited to an excited triplet state. Accordingly, use of phosphorescence from the excited triplet state for light emission enjoys a high energy utilization efficiency. However, the excited triplet state has a long lifetime, and therefore may cause energy deactivation owing to saturation of the excited state or the interaction with the excitons in the excited triplet state, and accordingly, in general, the quantum yield of phosphorescence is often high. On the other hand, in the exciplex, the exciton in the excited singlet state emits fluorescence as usual. On the other hand, the exciton in the excited triplet state emits fluorescence through reverse intersystem crossing to an excited singlet state. At that time, though emission at the same wavelength as that of fluorescence because of emission from the excited singlet state, the lifetime of light formed through reverse intersystem crossing from the excited triplet state to the excited singlet state (emission lifetime) is longer than that of ordinary fluorescence, and thus the emission is observed as a delayed fluorescence. This can be defined as a delayed fluorescence. Using the exciton transfer mechanism of the exciplex, the proportion of the compound in the excited singlet state that is formed only in a proportion of 25% in general can be increased up to more than 25%, and accordingly, the emission efficiency can be drastically improved.

Using the composition of the present invention as a material for a light-emitting layer, there can be provided excellent organic light-emitting devices such as an organic photoluminescent device (organic PL device) and an organic electroluminescent device (organic EL device). An organic photoluminescent device has a structure with at least a light-emitting layer formed on a substrate. An organic electroluminescent device has a structure of at least an anode, a cathode and an organic layer formed between the anode and the cathode. The organic layer contains at least a light-emitting layer, and may be formed of a light-emitting layer alone, or may have any other one or more organic layers in addition to a light-emitting layer. The other organic layers include a hole transport layer, a hole injection layer, an electron blocking layer, a hole blocking layer, an electron injection layer, an electron transport layer, and an exciton blocking layer. The hole transport layer may be a hole injection transport layer having a hole injection function, and the electron transport layer may be an electron injection transport layer having an electron injection function. A specific configuration example of an organic electroluminescent device is shown in FIG. 2. In FIG. 2, 1 is a substrate, 2 is an anode, 3 is a hole injection layer, 4 is a hole transport layer, 5 is a light-emitting layer, 6 is an electron transport layer, and 7 is a cathode.

In the following, the constituent members and the layers of the organic electroluminescent device are described. The description of the substrate and the light-emitting layer given below may apply to the substrate and the light-emitting layer of an organic photoluminescent device.

### (Substrate)

The organic electroluminescent device of the invention is preferably supported by a substrate. The substrate is not particularly limited and may be those that have been commonly used in an organic electroluminescent device, and examples thereof used include those formed of glass, transparent plastics, quartz and silicon.

### (Anode)

The anode of the organic electroluminescent device used is preferably formed of, as an electrode material, a metal, an alloy, or an electroconductive compound each having a large work function (4 eV or more), or a mixture thereof. Specific examples of the electrode material include a metal, such as Au, and an electroconductive transparent material, such as CuI, indium tin oxide (ITO), SnO₂ and ZnO. A material that is amorphous and is capable of forming a transparent electroconductive film, such as IDIXO (In₂O₃—ZnO), may also be used. The anode may be formed in such a manner that the electrode material is formed into a thin film by such a method as vapor deposition or sputtering, and the film is patterned into a desired pattern by a photolithography method, or in the case where the pattern may not require high accuracy (for example, approximately 100 μm or more), the pattern may be formed with a mask having a desired shape on vapor deposition or sputtering of the electrode material. In alternative, in the case where a material capable of being coated, such as an organic electroconductive compound, is used, a wet film forming method, such as a printing method and a coating method, may be used. In the case where emitted light is to be taken out through the anode, the anode preferably has a transmittance of more than 10%, and the anode preferably has a sheet resistance of several hundred Ω/sq or less. The thickness of the anode may be generally selected from a range of from 10 to 1,000 nm, and preferably from 10 to 200 nm, while depending on the material used.

### (Cathode)

The cathode is preferably formed of as an electrode material a metal (which is referred to as an electron injection metal), an alloy, or an electroconductive compound, having a small work function (4 eV or less), or a mixture thereof. Specific examples of the electrode material include sodium, a sodium-potassium alloy, magnesium, lithium, a magnesium-cupper mixture, a magnesium-silver mixture, a magnesium-aluminum mixture, a magnesium-indium mixture, an aluminum-aluminum oxide (Al₂O₃) mixture, indium, a lithium-aluminum mixture, and a rare earth metal. Among these, a mixture of an electron injection metal and a second metal that is a stable metal having a larger work function than the electron injection metal, for example, a magnesium-silver mixture, a magnesium-aluminum mixture, a magnesium-indium mixture, an aluminum-aluminum oxide (Al₂O₃) mixture, a lithium-aluminum mixture, and aluminum, is preferred from the standpoint of the electron injection property and the durability against oxidation and the like. The cathode may be produced by forming the electrode material into a thin film by such a method as vapor deposition or sputtering. The cathode preferably has a sheet resistance of several hundred Ω/sq or less, and the thickness thereof may be generally selected from a range of from 10 nm to 5 μm, and preferably from 50 to 200 nm. For transmitting the emitted light, any one of the anode and the cathode of the organic electroluminescent device is preferably transparent or translucent, thereby enhancing the light emission luminance.

The cathode may be formed with the electroconductive transparent materials described for the anode, thereby forming a transparent or translucent cathode, and by applying the cathode, a device having an anode and a cathode, both of which have transmittance, may be produced.

### (Light-Emitting Layer)

The light-emitting layer is a layer in which holes and electrons injected from an anode and a cathode are recombined to give excitons for light emission. In the organic light-emitting device of the present invention, the light-emitting layer contains the composition of the present invention. The light-emitting layer may be formed of the composition of the present invention alone, or may contain any other material, but is preferably a film-formed composition of the present invention. Regarding the description of the film-formed composition, reference may be made to the description in the section of the above-mentioned [Form of Composition].

In the organic light-emitting device or the organic electroluminescent device of the present invention, light emission occurs from the exciplex formed in the light-emitting layer, or from the fluorescent compound optionally added to the composition, or from both the two. The emission includes fluorescent emission and delayed fluorescent emission. A part of emission may include emission from the donor compound or the acceptor compound.

### (Injection Layer)

The injection layer is a layer that is provided between the electrode and the organic laver, for decreasing the driving voltage and enhancing the light emission luminance, and includes a hole injection layer and an electron injection layer, which may be provided between the anode and the light-emitting layer or the hole transport layer and between the cathode and the light emitting layer or the electron transport layer. The injection layer may be provided depending on necessity.

### (Blocking Layer)

The blocking layer is a layer that is capable of inhibiting charges (electrons or holes) and/or excitons present in the light-emitting layer from being diffused outside the light-emitting layer. The electron blocking layer may be disposed between the light-emitting layer and the hole transport layer, and inhibits electrons from passing through the light-emitting layer toward the hole transport layer. Similarly, the hole blocking layer may be disposed between the light-emitting layer and the electron transport layer, and inhibits holes from passing through the light-emitting layer toward the electron transport layer. The blocking layer may also be used for inhibiting excitons from being diffused outside the light-emitting layer. Thus, the electron blocking layer and the hole blocking layer each may also have a function as an exciton blocking layer. The term “the electron blocking layer” or “the exciton blocking layer” referred to herein is intended to include a layer that has both the functions of an electron blocking layer and an exciton blocking layer by one layer.

### (Hole Blocking Layer)

The hole blocking layer has the function of an electron transport layer in a broad sense. The hole blocking layer has a function of inhibiting holes from reaching the electron transport layer while transporting electrons, and thereby enhances the recombination probability of electrons and holes in the light-emitting layer. As the material for the hole blocking layer, the material for the electron transport layer to be mentioned below may be used optionally.

### (Electron Blocking Layer)

The electron blocking layer has the function of transporting holes in a broad sense. The electron blocking layer has a function of inhibiting electrons from reaching the hole transport layer while transporting holes, and thereby enhances the recombination probability of electrons and holes in the light-emitting layer.

### (Exciton Blocking Layer)

The exciton blocking layer is a layer for inhibiting excitons generated through recombination of holes and electrons in the light-emitting layer from being diffused to the charge transporting layer, and the use of the layer inserted enables effective confinement of excitons in the light-emitting layer, and thereby enhances the light emission efficiency of the device. The exciton blocking layer may be inserted adjacent to the light-emitting layer on any of the side of the anode and the side of the cathode, and on both the sides. Specifically, in the case where the exciton blocking laver is present on the side of the anode, the layer may be inserted between the hole transport layer and the light-emitting layer and adjacent to the light-emitting layer, and in the case where the layer is inserted on the side of the cathode, the layer may be inserted between the light-emitting layer and the cathode and adjacent to the light-emitting layer. Between the anode and the exciton blocking layer that is adjacent to the light-emitting layer on the side of the anode, a hole injection layer, an electron blocking layer and the like may be provided, and between the cathode and the exciton blocking layer that is adjacent to the light-emitting layer on the side of the cathode, an electron injection layer, an electron transport layer, a hole blocking layer and the like may be provided. In the case where the blocking layer is provided, preferably, at least one of the excited singlet energy and the excited triplet energy of the material used as the blocking layer is higher than the excited singlet energy and the excited triplet energy of the light-emitting layer, respectively, of the light-emitting material.

### (Hole Transport Layer)

The hole transport layer is formed of a hole transport material having a function of transporting holes, and the hole transport layer may be provided as a single layer or plural layers.

The hole transport material has one of injection or transporting property of holes and blocking property of electrons, and may be any of an organic material and an inorganic material. Examples of known hole transport materials that may be used herein include a triazole derivative, an oxadiazole derivative, an imidazole derivative, a carbazole derivative, an indolocarbazole derivative, a polyarylalkane derivative, a pyrazoline derivative, a pyrazolone derivative, a phenylenediamine derivative, an arylamine derivative, an amino-substituted chalcone derivative, an oxazole derivative, a styrylanthracene derivative, a fluorenone derivative, a hydrazone derivative, a stilbene derivative, a silazane derivative, an aniline copolymer and an electroconductive polymer oligomer, particularly a thiophene oligomer. Among these, a porphyrin compound, an aromatic tertiary amine compound and a styrylamine compound are preferably used, and an aromatic tertiary amine compound is more preferably used.

### (Electron Transport Layer)

The electron transport layer is formed of a material having a function of transporting electrons, and the electron transport layer may be a single layer or may be formed of plural layers.

The electron transport material (often also acting as a hole blocking material) may have a function of transmitting the electrons injected from a cathode to a light-emitting layer. The electron transport layer usable here includes, for example, nitro-substituted fluorene derivatives, diphenylquinone derivatives, thiopyran dioxide derivatives, carbodiimides, fluorenylidenemethane derivatives, anthraquinodimethane and anthrone derivatives, oxadiazole derivatives, etc. Further, thiadiazole derivatives derived from the above-mentioned oxadiazole derivatives by substituting the oxygen atom in the oxadiazole ring with a sulfur atom, and quinoxaline derivatives having a quinoxaline ring known as an electron-attractive group are also usable as the electron transport material. Further, polymer materials prepared by introducing these materials into the polymer chain, or having these material in the polymer main chain are also usable.

In producing an organic electroluminescent device, the compound represented by the formula (1) may be used not only in a light-emitting layer but also in any other layer than a light-emitting layer. In that case, the compound represented by the formula (1) that is used in a light-emitting layer may be the same as or different from the compound represented by the formula (1) that is used in any other layer than a light-emitting layer. For example, the compound represented by the formula (1) can be used in the above-mentioned injection layer, blocking layer, hole blocking layer, electron blocking layer, exciton blocking layer, hole transport layer and electron transport layer. The method for forming these layers is not specifically limited, and the layers may be formed in any of a dry process or a wet process.

Preferred materials for use for the organic electroluminescent device are concretely exemplified below. However, the materials for use in the present invention are not limitatively interpreted by the following exemplary compounds. Compounds, even though exemplified as materials having a specific function, can also be used as other materials having any other function.

First, preferred compounds for use as a host material in a light-emitting layer (composition) are mentioned below.

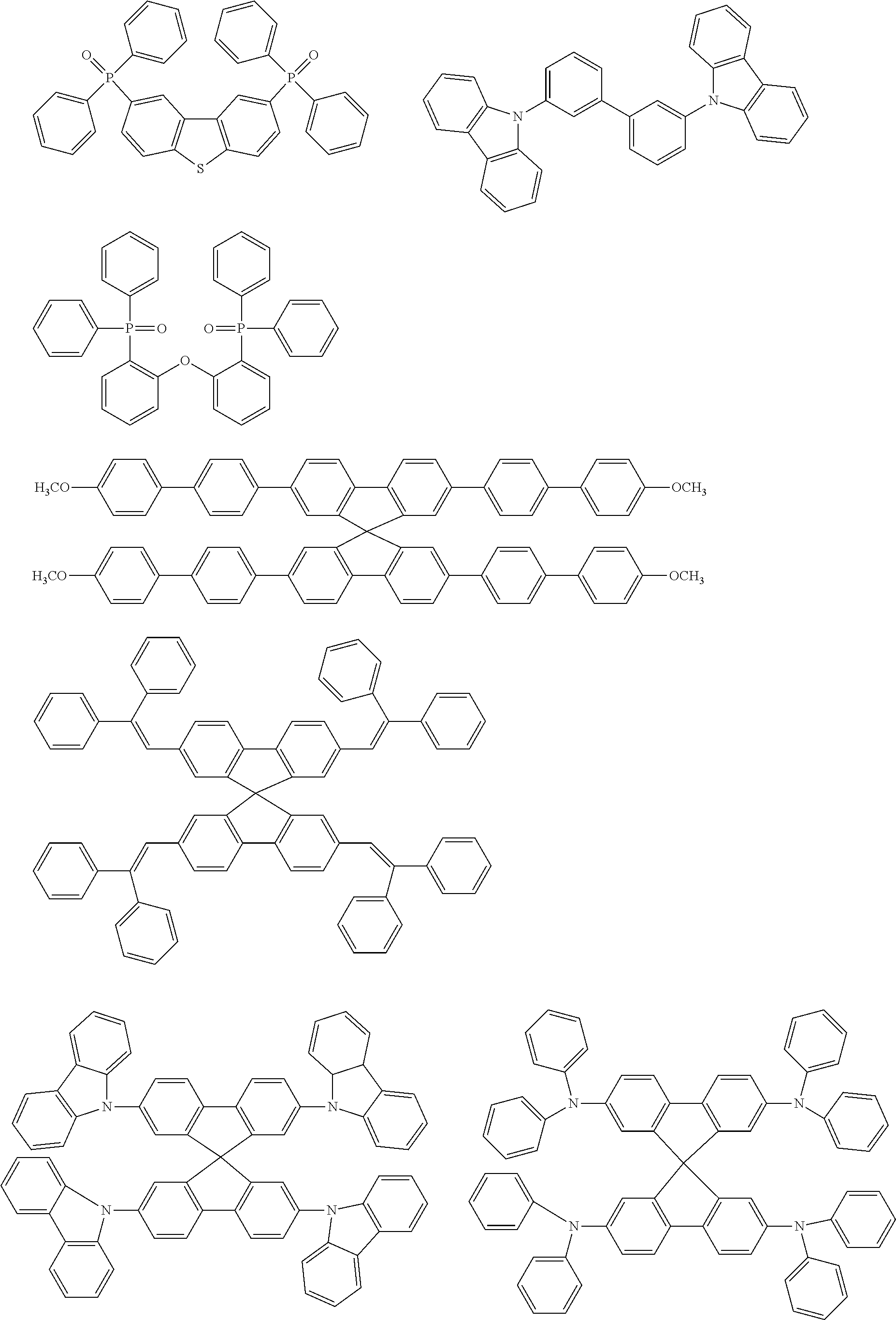

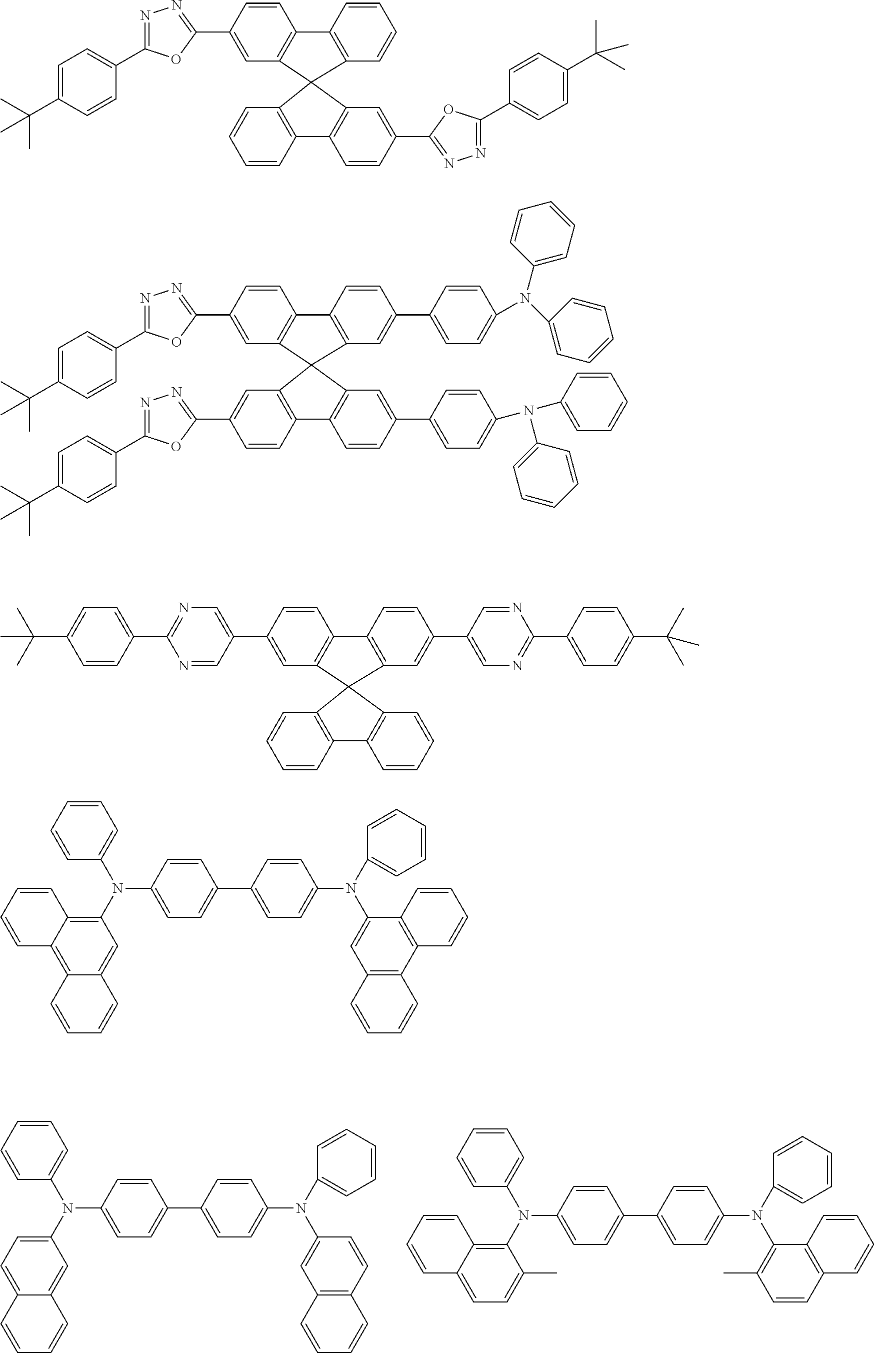

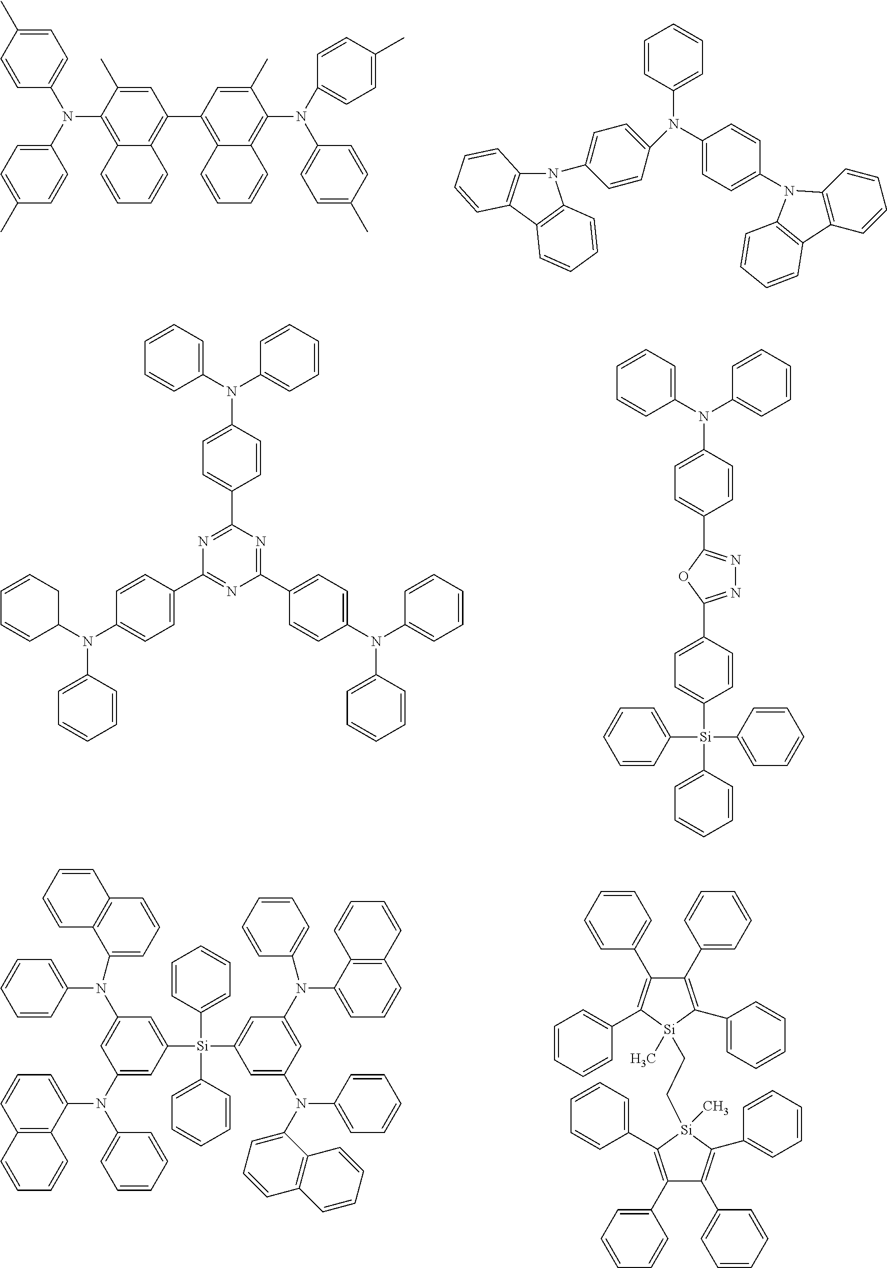

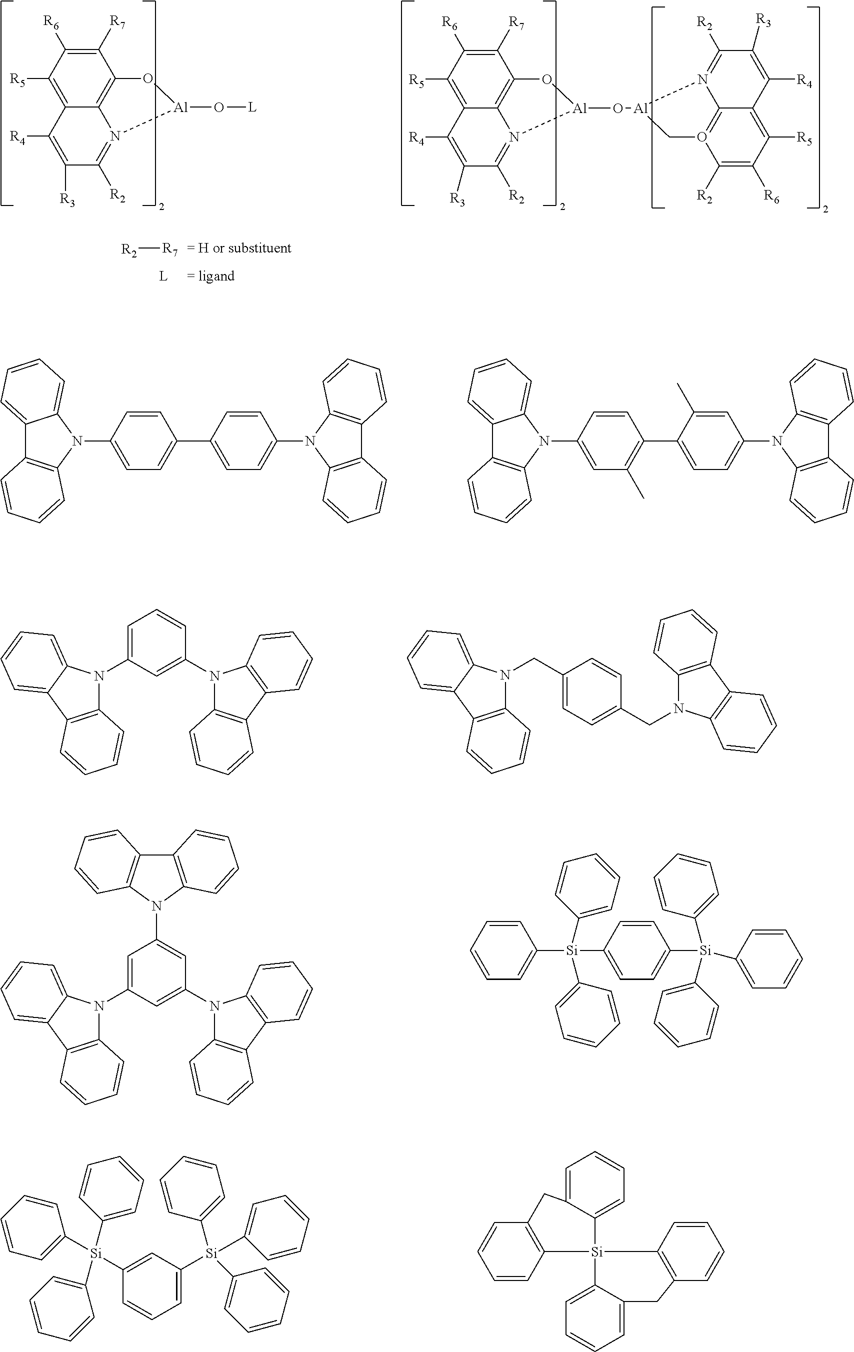

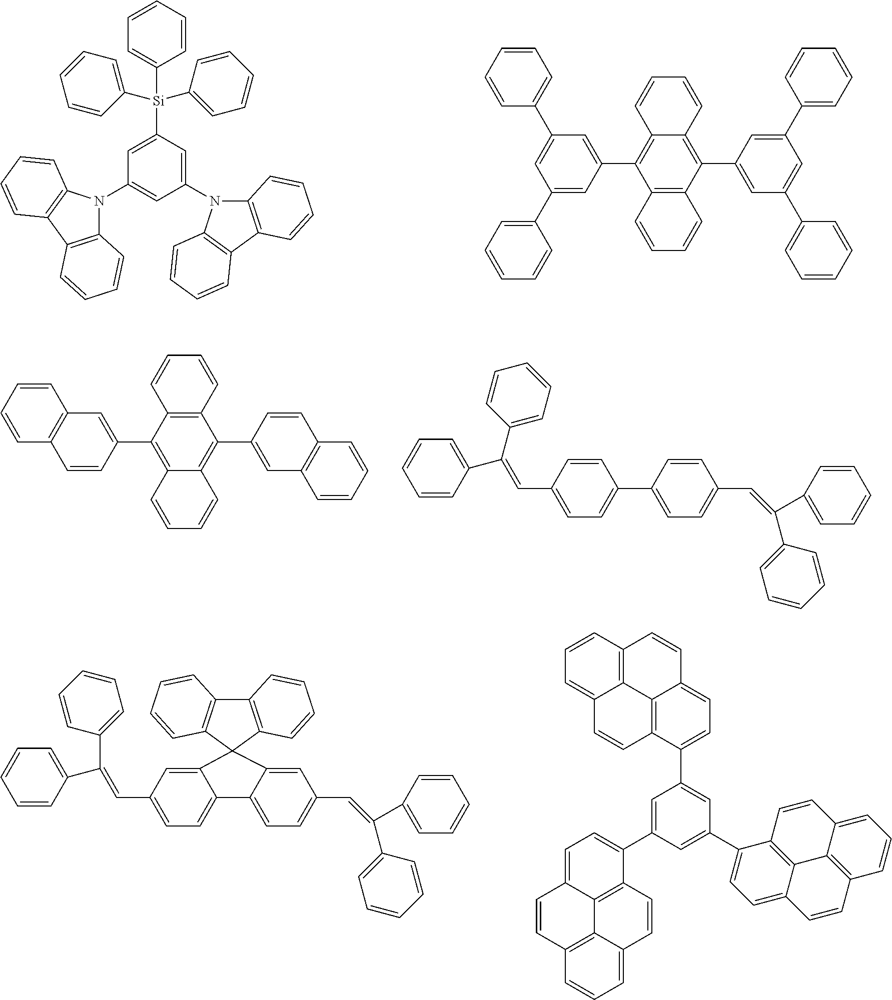

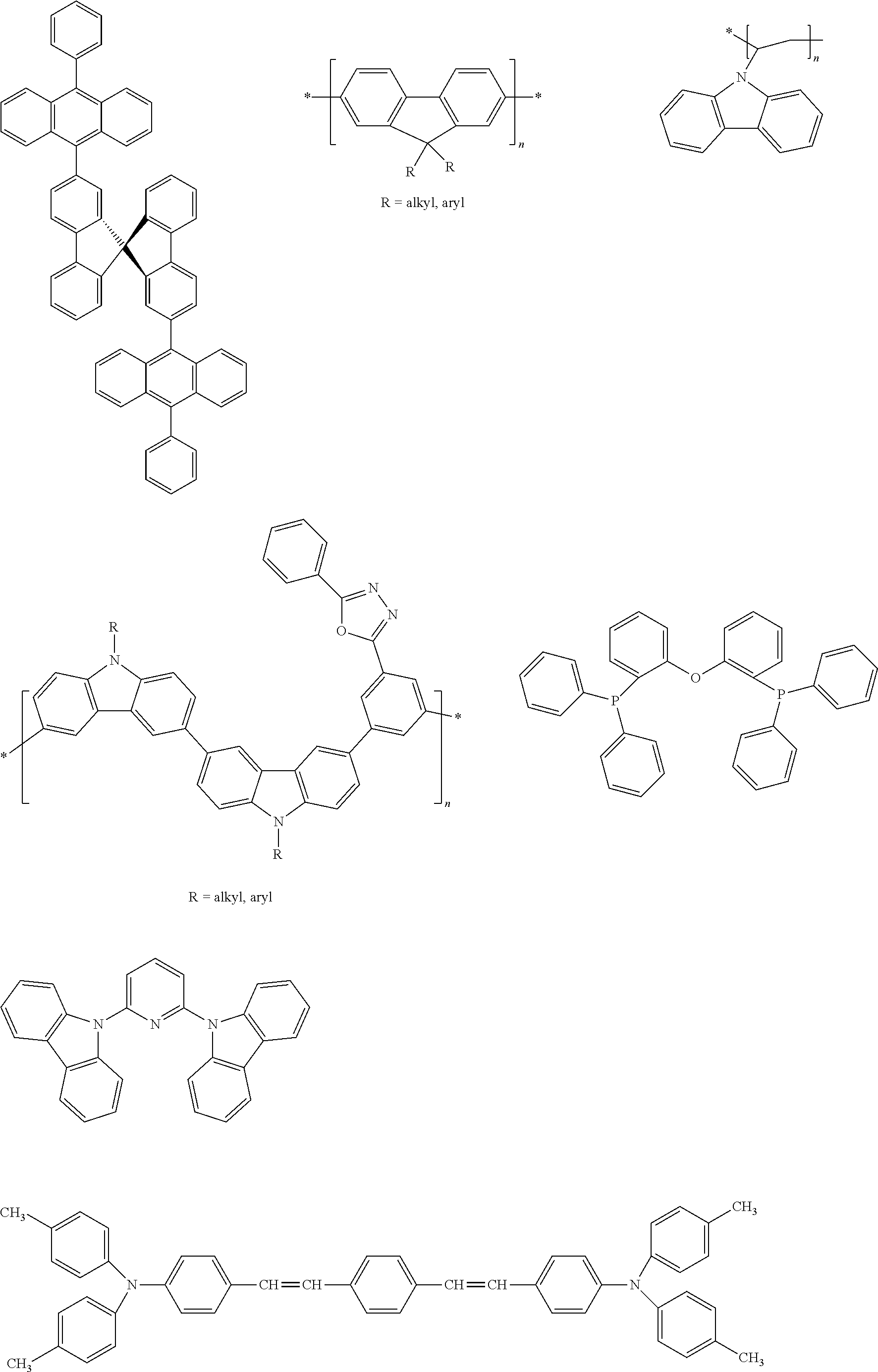

Next, examples of preferred compounds for use as a hole injection material are mentioned below.

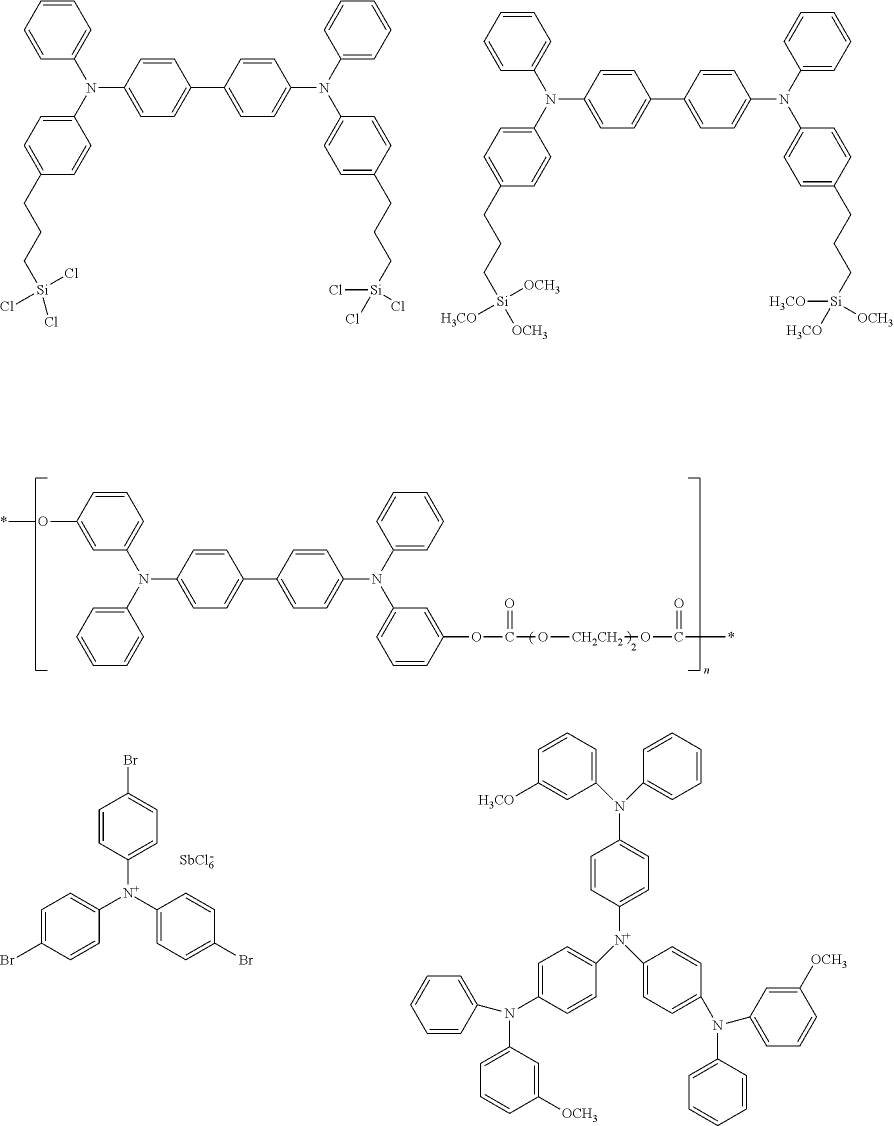

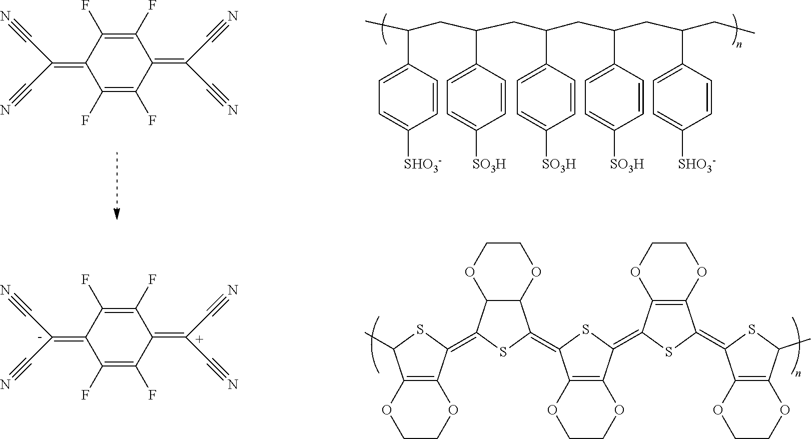

Next, examples of preferred compounds for use as a hole transport material are mentioned below.

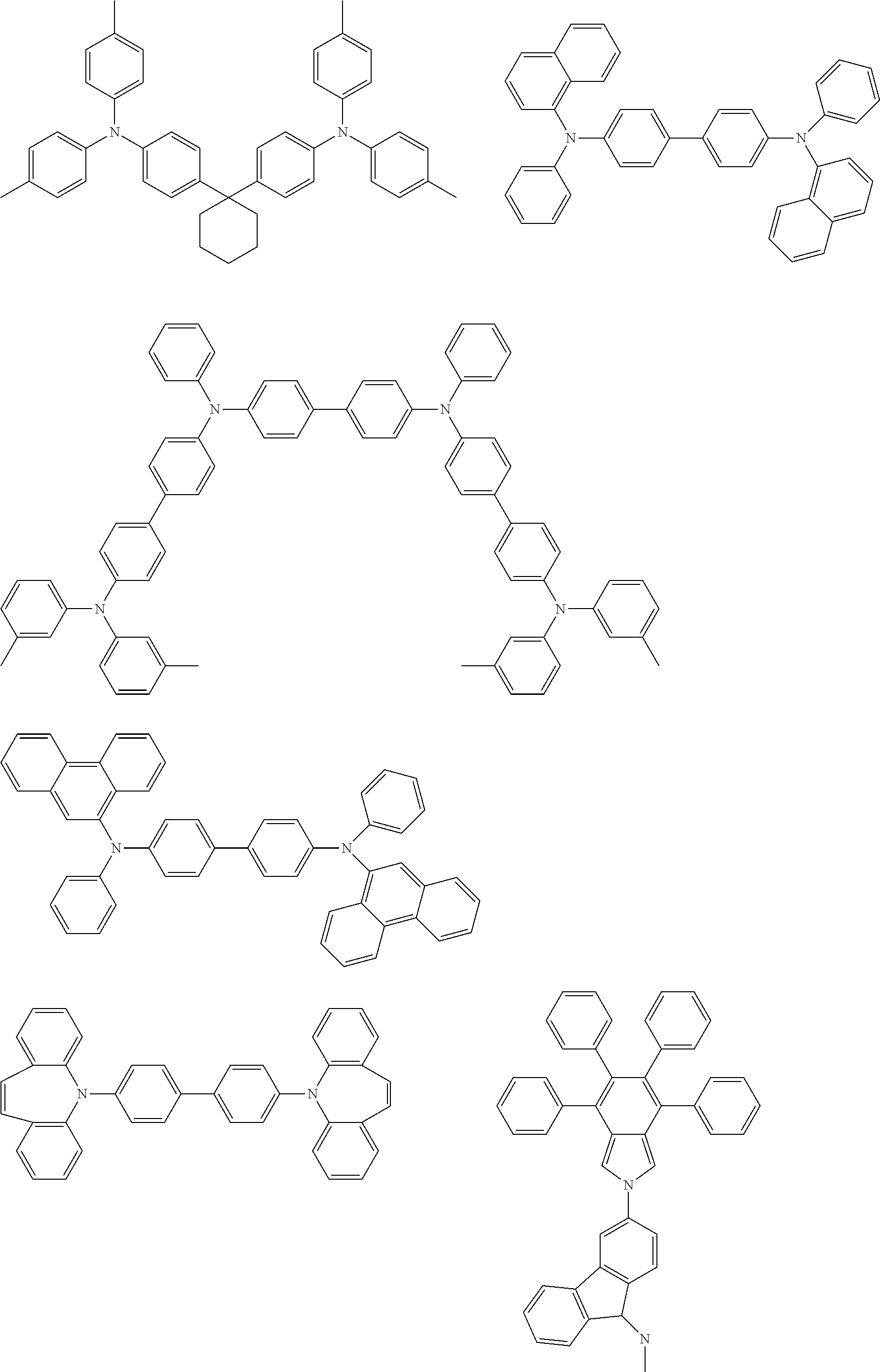

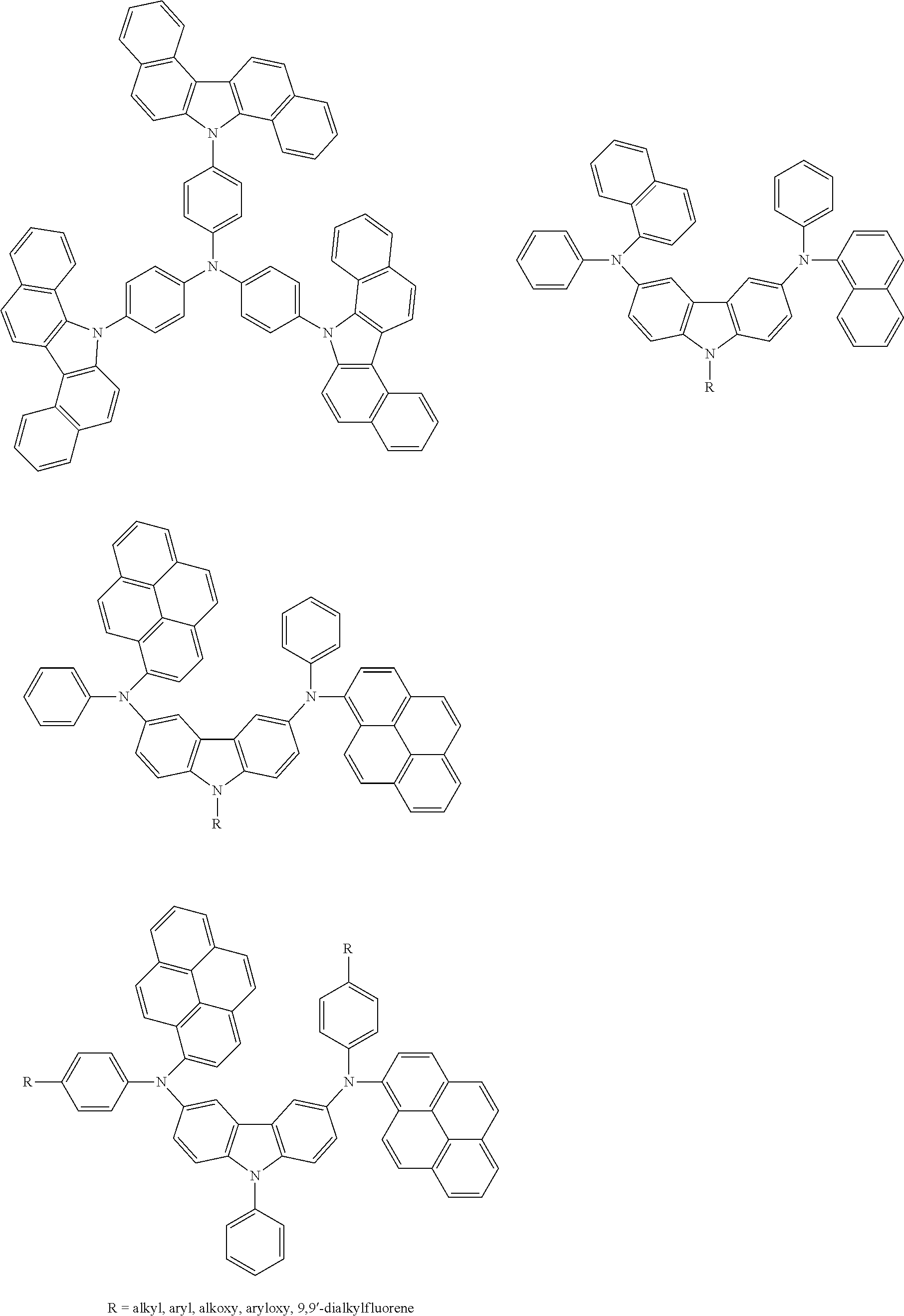

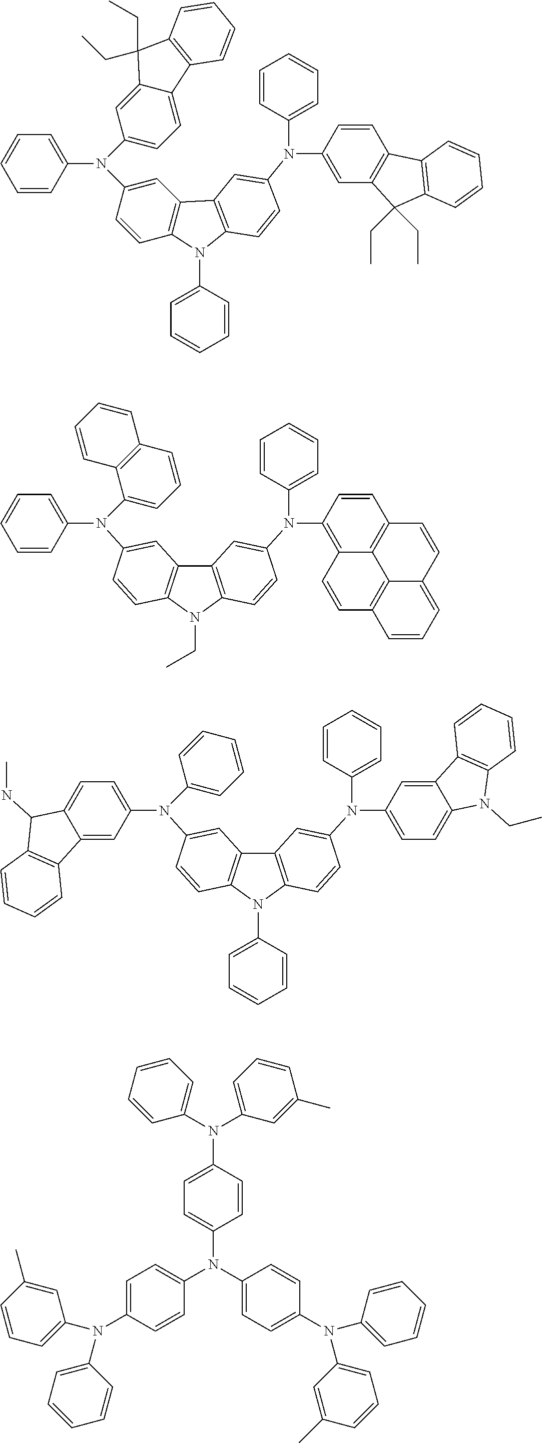 [SMILES: CCC1(CC)c2ccccc2-c2ccc(N(c3ccccc3)c3ccc4c(c3)c3cc(N(c5ccccc5)c5ccc6c(c5)C(CC)(CC)c5ccccc5-6)ccc3n4-c3ccccc3)cc21 ; CCn1c2ccc(N(c3ccccc3)c3cccc4ccccc34)cc2c2cc(N(c3ccccc3)c3ccc4ccc5cccc6ccc3c4c56)ccc21 ; CCn1c2ccccc2c2cc(N(c3ccccc3)c3ccc4c(c3)c3cc(N(c5ccccc5)c5ccc6c(c5)-c5ccccc5C6NC)ccc3n4-c3ccccc3)ccc21 ; Cc1cccc(N(c2ccccc2)c2ccc(N(c3ccc(N(c4ccccc4)c4cccc(C)c4)cc3)c3ccc(N(c4ccccc4)c4cccc(C)c4)cc3)cc2)c1]

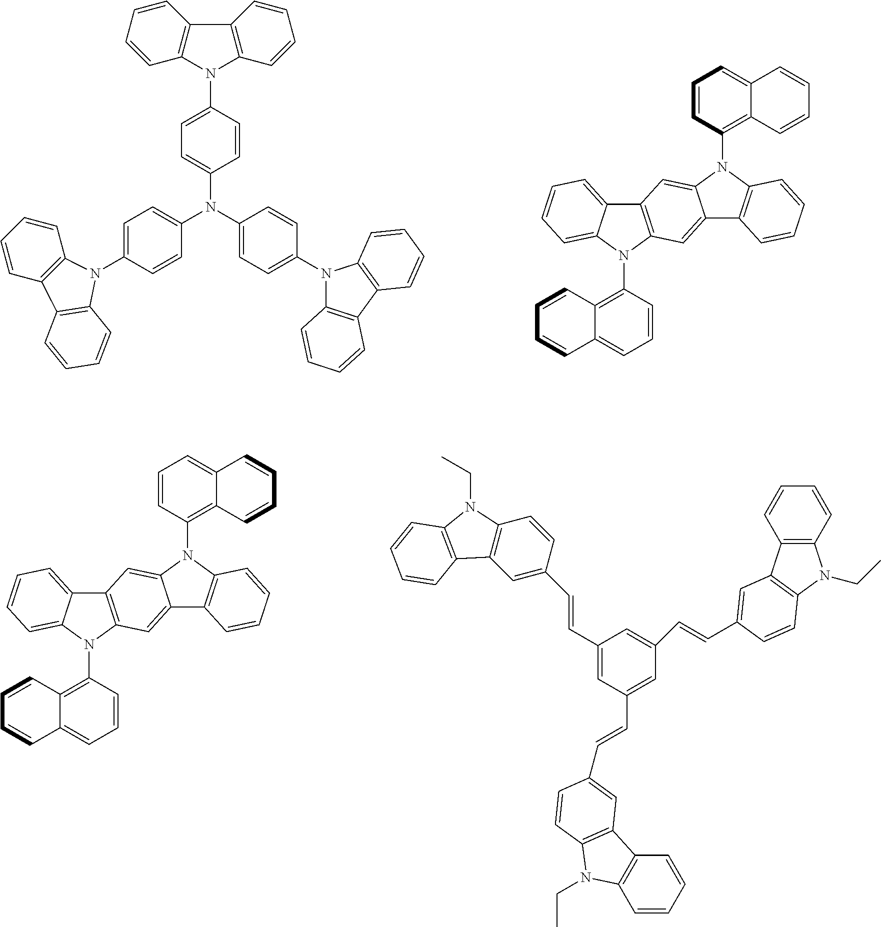

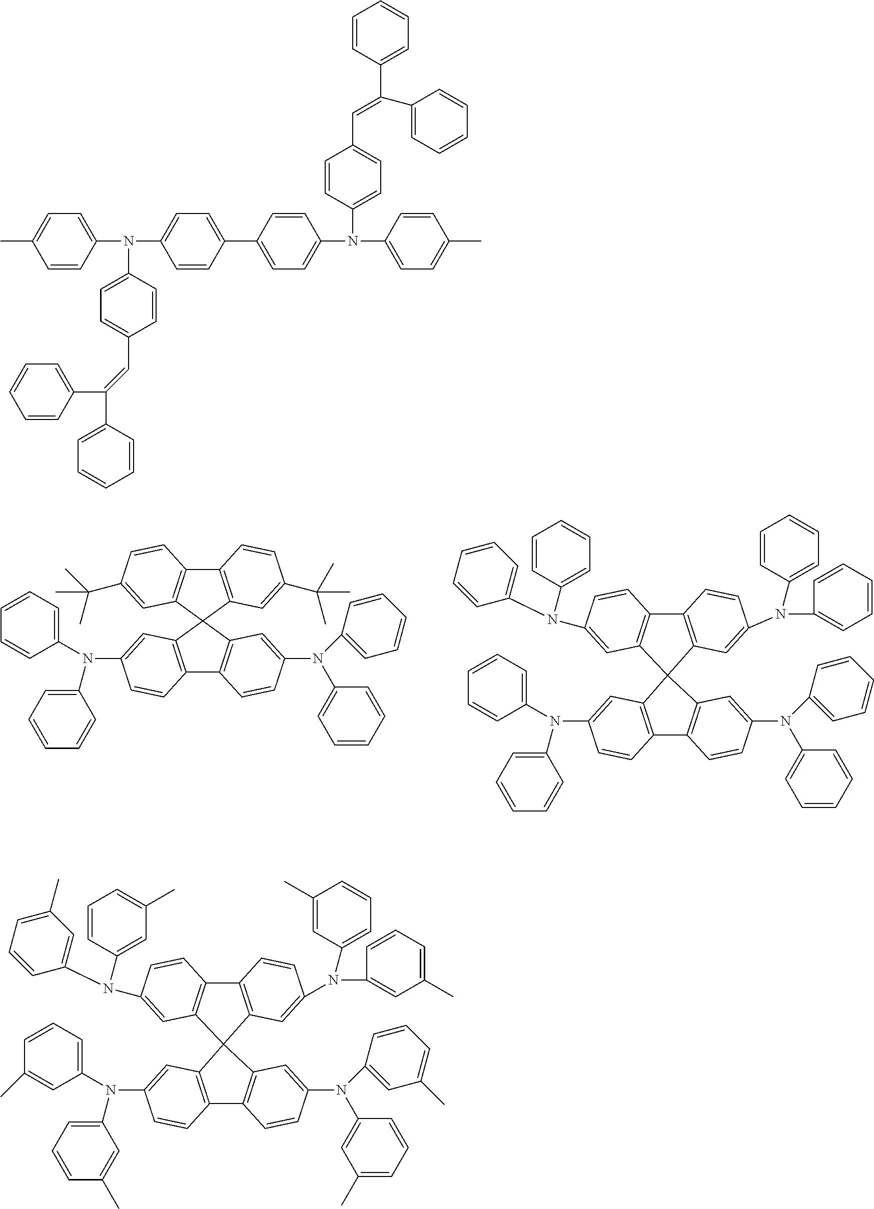

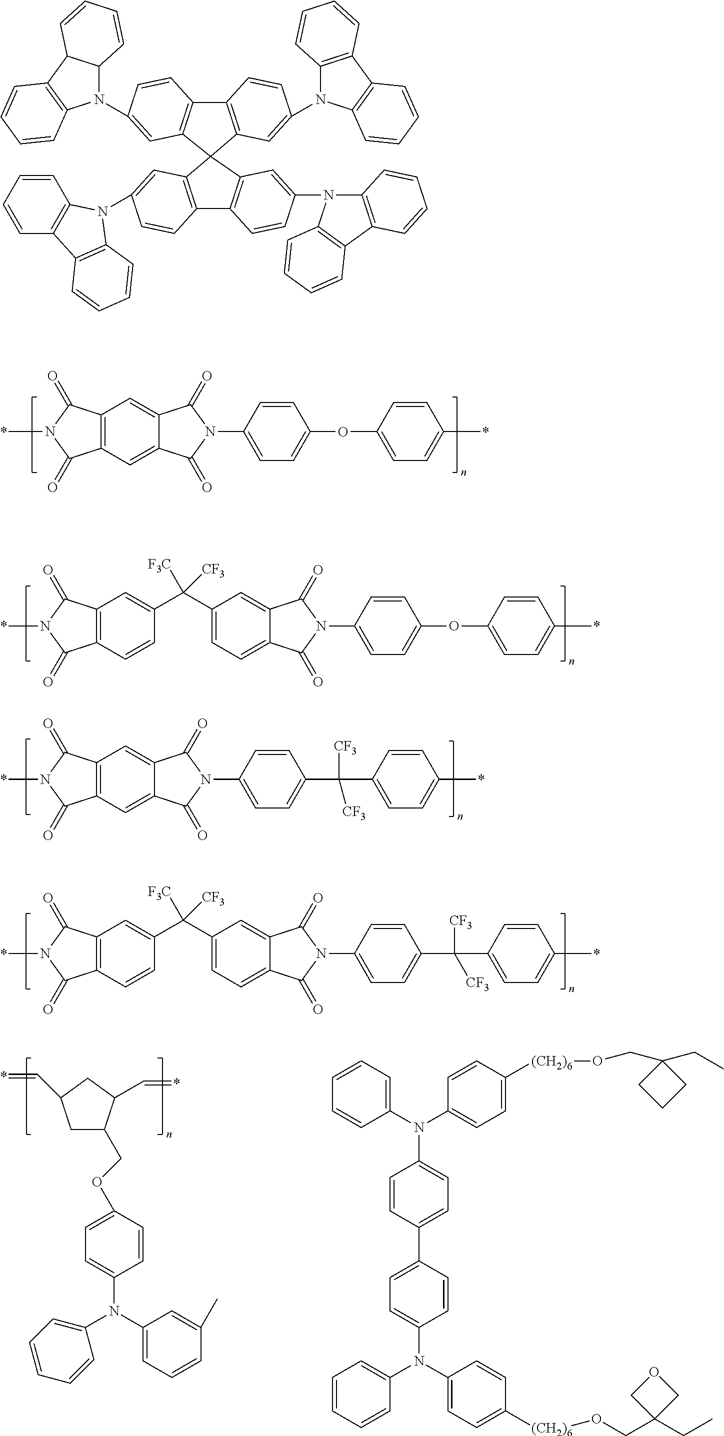

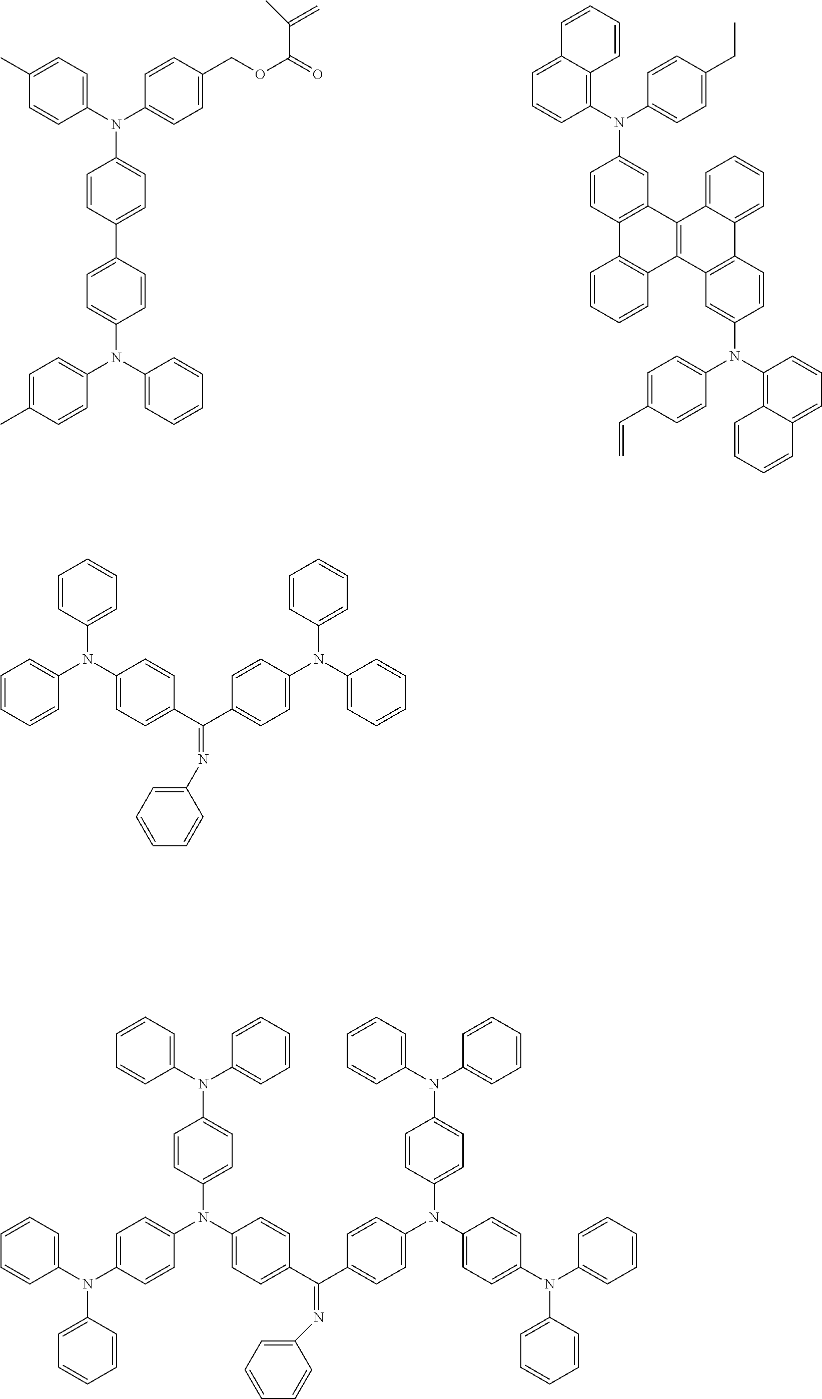 [SMILES: C=C(C)C(=O)OCc1ccc(N(c2ccc(C)cc2)c2ccc(-c3ccc(N(c4ccccc4)c4ccc(C)cc4)cc3)cc2)cc1 ; C=Cc1ccc(N(c2ccc3c4ccccc4c4c5cc(N(c6ccc(CC)cc6)c6cccc7ccccc67)ccc5c5ccccc5c4c3c2)c2cccc3ccccc23)cc1 ; c1ccc(N=C(c2ccc(N(c3ccccc3)c3ccccc3)cc2)c2ccc(N(c3ccccc3)c3ccccc3)cc2)cc1 ; c1ccc(N=C(c2ccc(N(c3ccc(N(c4ccccc4)c4ccccc4)cc3)c3ccc(N(c4ccccc4)c4ccccc4)cc3)cc2)c2ccc(N(c3ccc(N(c4ccccc4)c4ccccc4)cc3)c3ccc(N(c4ccccc4)c4ccccc4)cc3)cc2)cc1]

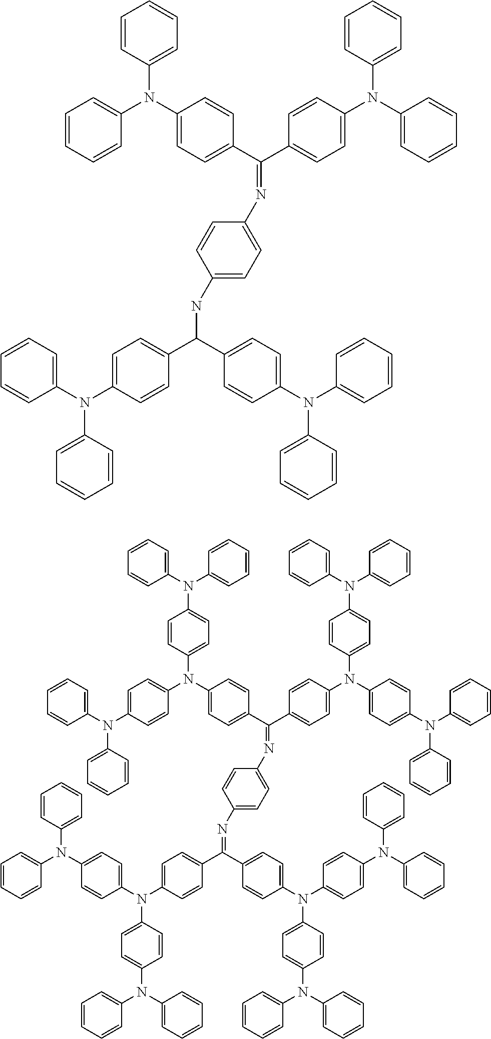 [SMILES: c1ccc(N(c2ccccc2)c2ccc(C(=Nc3ccc(NC(c4ccc(N(c5ccccc5)c5ccccc5)cc4)c4ccc(N(c5ccccc5)c5ccccc5)cc4)cc3)c3ccc(N(c4ccccc4)c4ccccc4)cc3)cc2)cc1 ; c1ccc(N(c2ccccc2)c2ccc(N(c3ccc(C(=Nc4ccc(N=C(c5ccc(N(c6ccc(N(c7ccccc7)c7ccccc7)cc6)c6ccc(N(c7ccccc7)c7ccccc7)cc6)cc5)c5ccc(N(c6ccc(N(c7ccccc7)c7ccccc7)cc6)c6ccc(N(c7ccccc7)c7ccccc7)cc6)cc5)cc4)c4ccc(N(c5ccc(N(c6ccccc6)c6ccccc6)cc5)c5ccc(N(c6ccccc6)c6ccccc6)cc5)cc4)cc3)c3ccc(N(c4ccccc4)c4ccccc4)cc3)cc2)cc1]

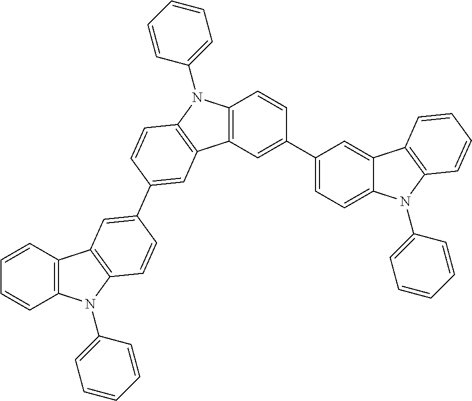 [SMILES: c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1]

Next, examples of preferred compounds for use as an electron blocking material are mentioned below.

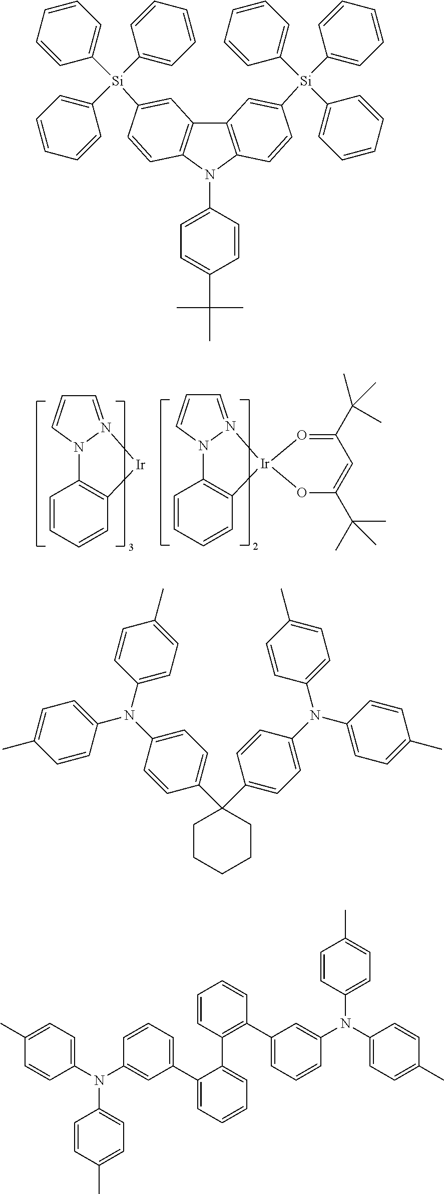

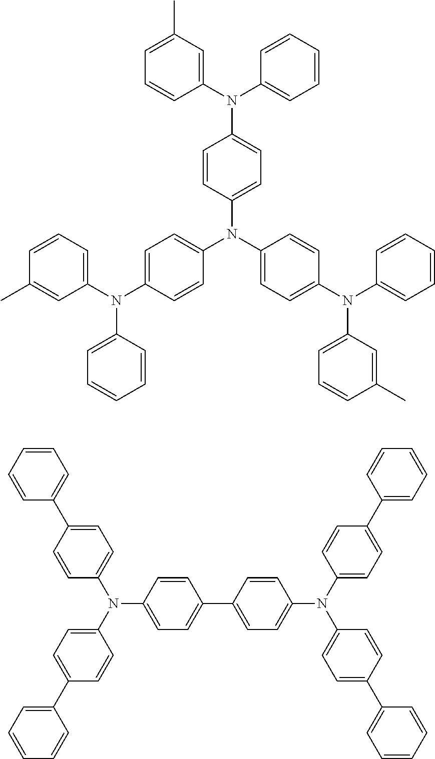 [SMILES: Cc1cccc(N(c2ccccc2)c2ccc(N(c3ccc(N(c4ccccc4)c4cccc(C)c4)cc3)c3ccc(N(c4ccccc4)c4cccc(C)c4)cc3)cc2)c1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

Next, examples of preferred compounds for use as a hole blocking material are mentioned below.

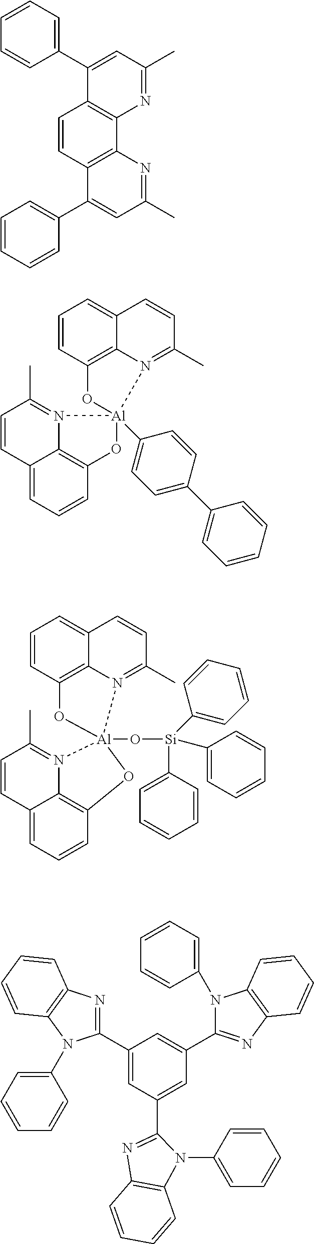

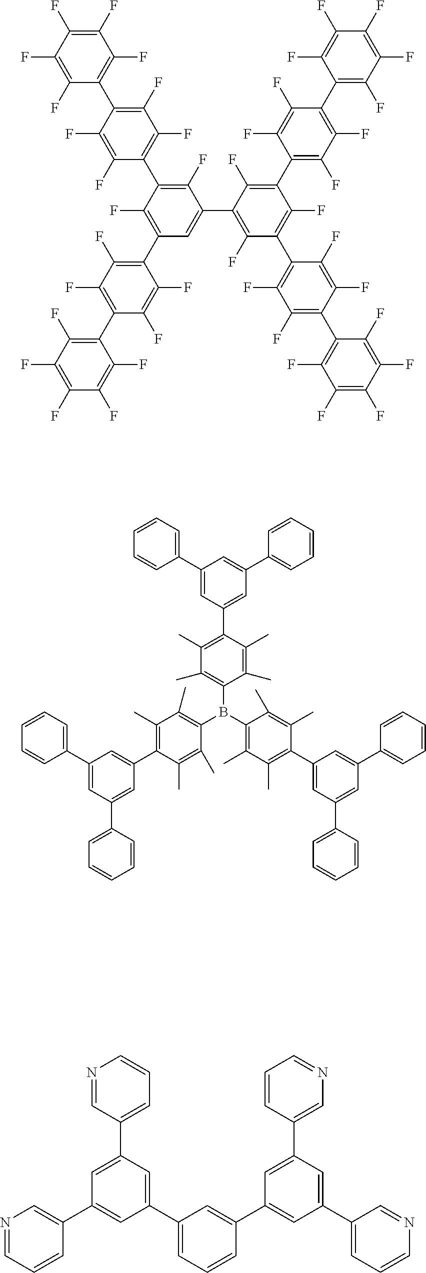 [SMILES: Fc1c(F)c(F)c(-c2c(F)c(F)c(-c3cc(-c4c(F)c(-c5c(F)c(F)c(-c6c(F)c(F)c(F)c(F)c6F)c(F)c5F)c(F)c(-c5c(F)c(F)c(-c6c(F)c(F)c(F)c(F)c6F)c(F)c5F)c4F)c(F)c(-c4c(F)c(F)c(-c5c(F)c(F)c(F)c(F)c5F)c(F)c4F)c3F)c(F)c2F)c(F)c1F ; Cc1c(C)c(-c2cc(-c3ccccc3)cc(-c3ccccc3)c2)c(C)c(C)c1B(c1c(C)c(C)c(-c2cc(-c3ccccc3)cc(-c3ccccc3)c2)c(C)c1C)c1c(C)c(C)c(-c2cc(-c3ccccc3)cc(-c3ccccc3)c2)c(C)c1C ; c1cncc(-c2cc(-c3cccnc3)cc(-c3cccc(-c4cc(-c5cccnc5)cc(-c5cccnc5)c4)c3)c2)c1]

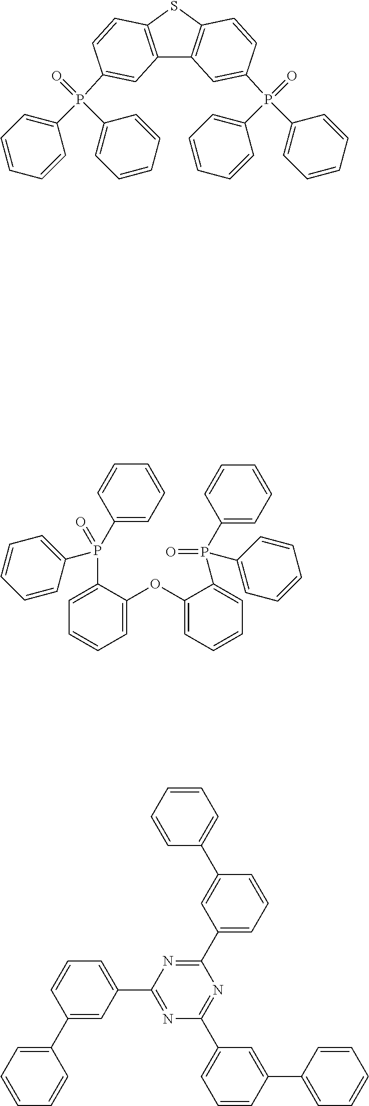 [SMILES: O=P(c1ccccc1)(c1ccccc1)c1ccc2sc3ccc(P(=O)(c4ccccc4)c4ccccc4)cc3c2c1 ; O=P(c1ccccc1)(c1ccccc1)c1ccccc1Oc1ccccc1P(=O)(c1ccccc1)c1ccccc1 ; c1ccc(-c2cccc(-c3nc(-c4cccc(-c5ccccc5)c4)nc(-c4cccc(-c5ccccc5)c4)n3)c2)cc1]

Next, examples of preferred compounds for use as an electron transport material are mentioned below.

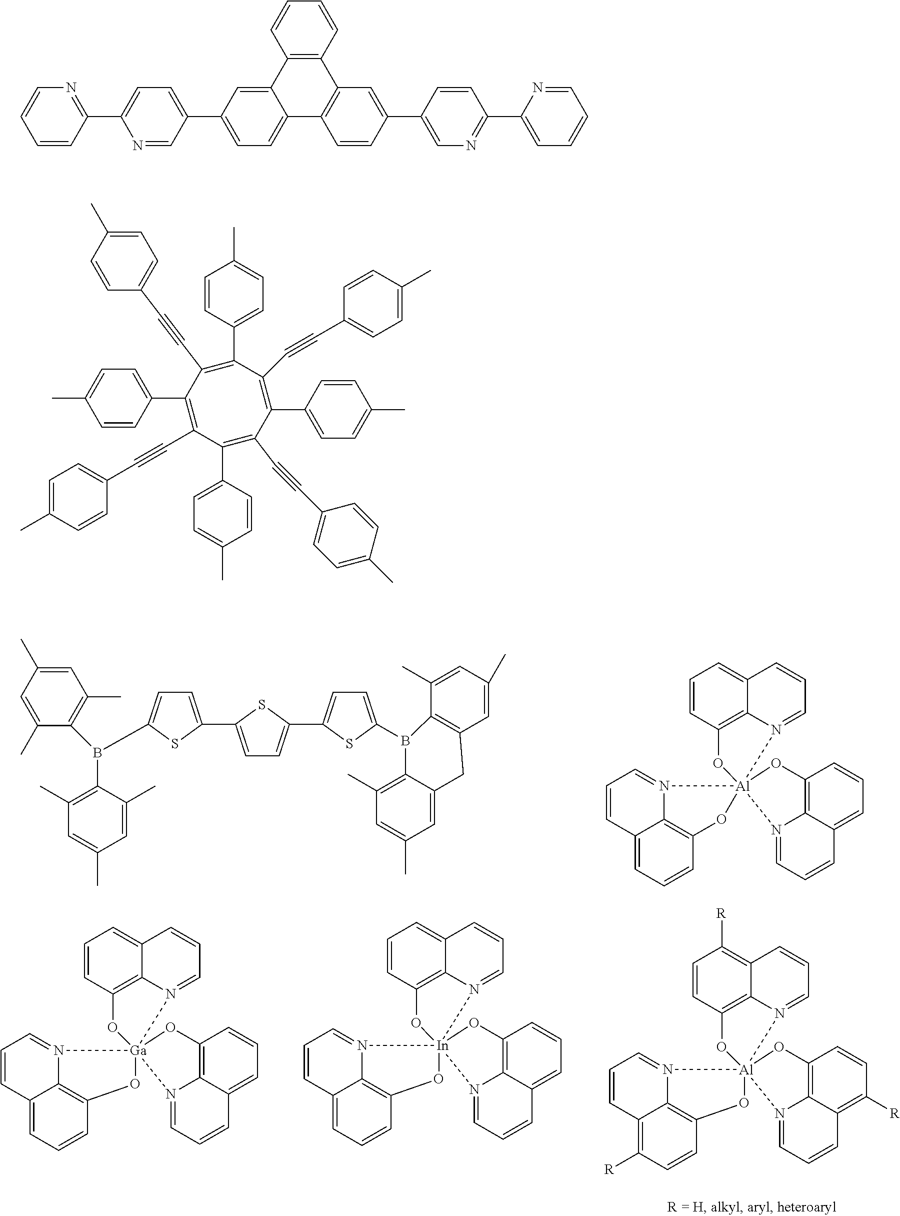

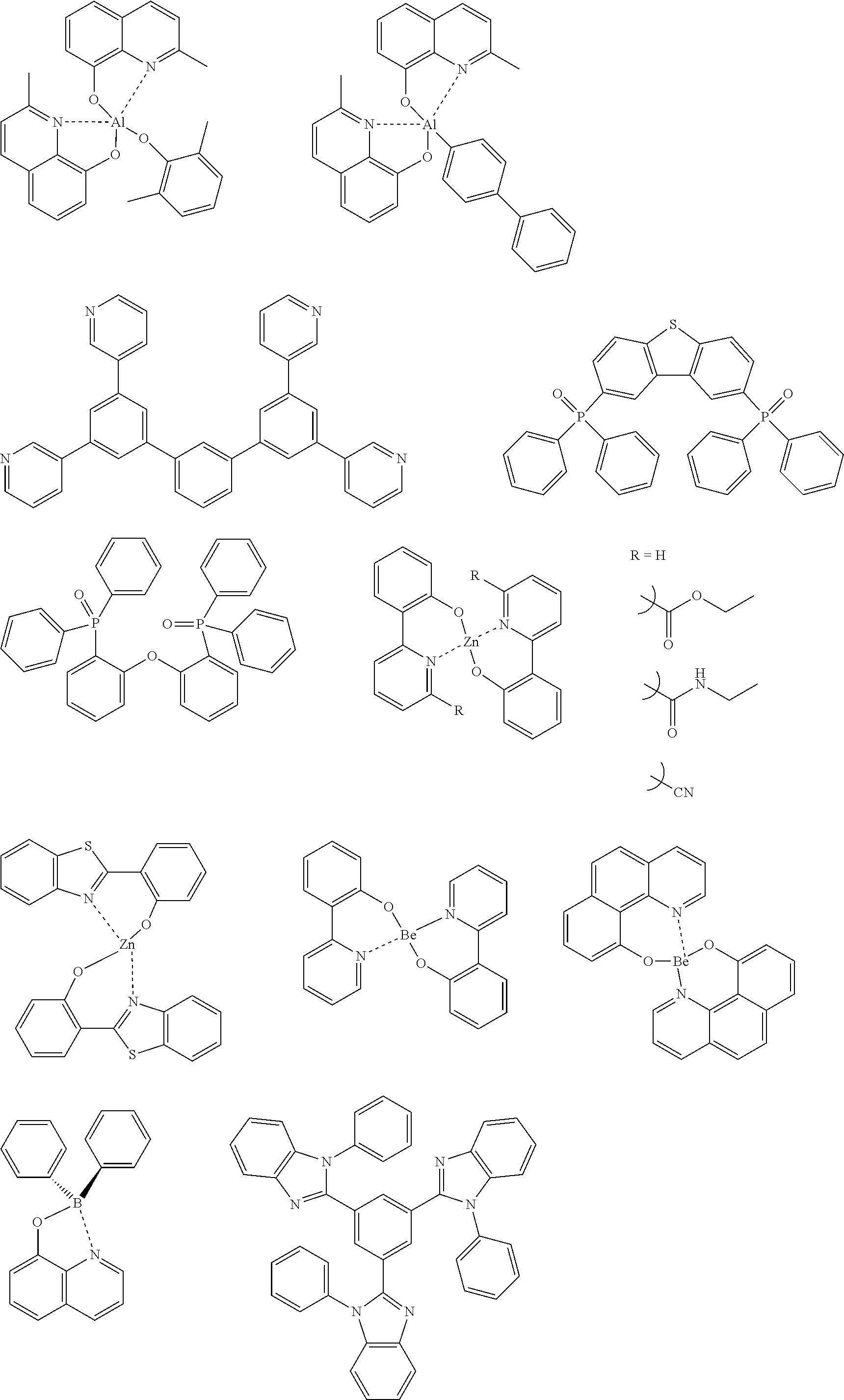

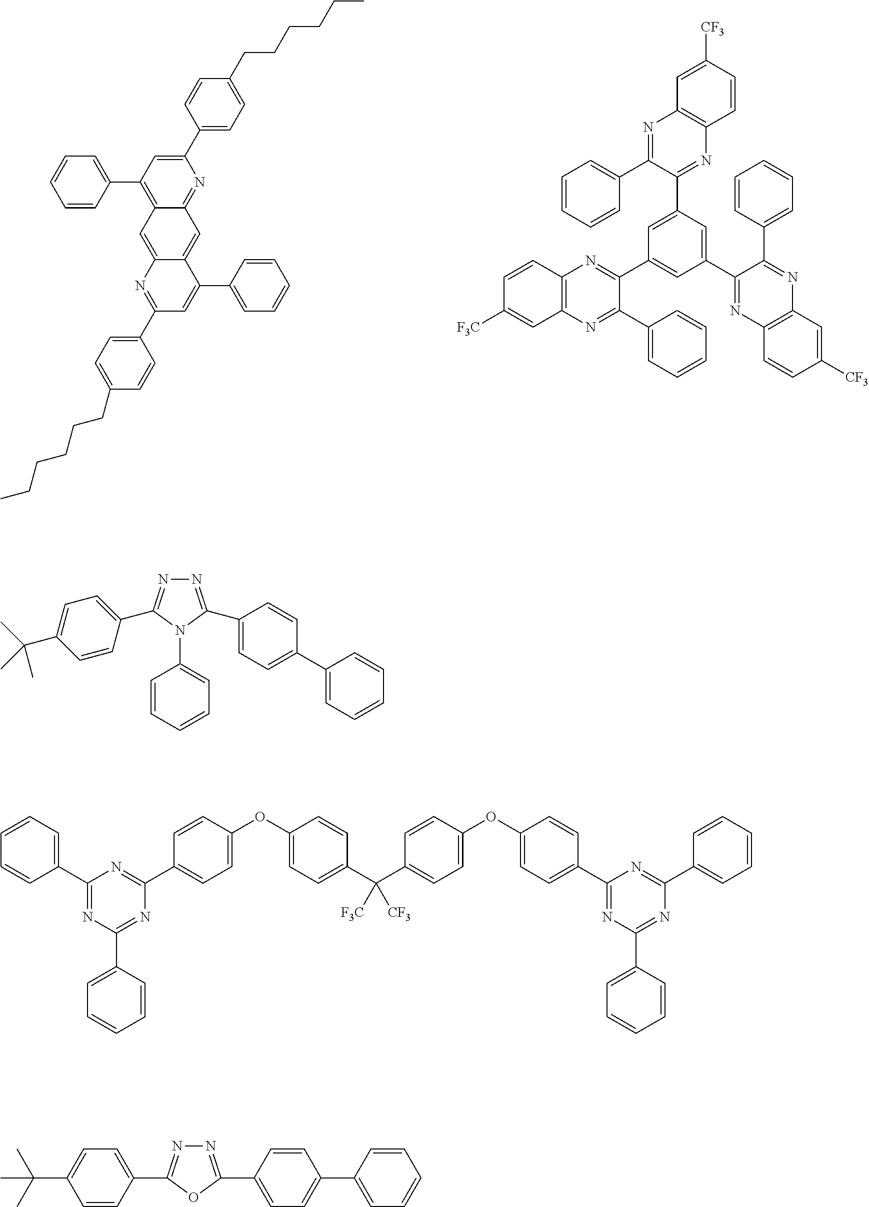 [SMILES: CCCCCCc1ccc(-c2cc(-c3ccccc3)c3cc4nc(-c5ccc(CCCCCC)cc5)cc(-c5ccccc5)c4cc3n2)cc1 ; FC(F)(F)c1ccc2nc(-c3cc(-c4nc5ccc(C(F)(F)F)cc5nc4-c4ccccc4)cc(-c4nc5ccc(C(F)(F)F)cc5nc4-c4ccccc4)c3)c(-c3ccccc3)nc2c1 ; CC(C)(C)c1ccc(-c2nnc(-c3ccc(-c4ccccc4)cc3)n2-c2ccccc2)cc1 ; FC(F)(F)C(c1ccc(Oc2ccc(-c3nc(-c4ccccc4)nc(-c4ccccc4)n3)cc2)cc1)(c1ccc(Oc2ccc(-c3nc(-c4ccccc4)nc(-c4ccccc4)n3)cc2)cc1)C(F)(F)F ; CC(C)(C)c1ccc(-c2nnc(-c3ccc(-c4ccccc4)cc3)o2)cc1]

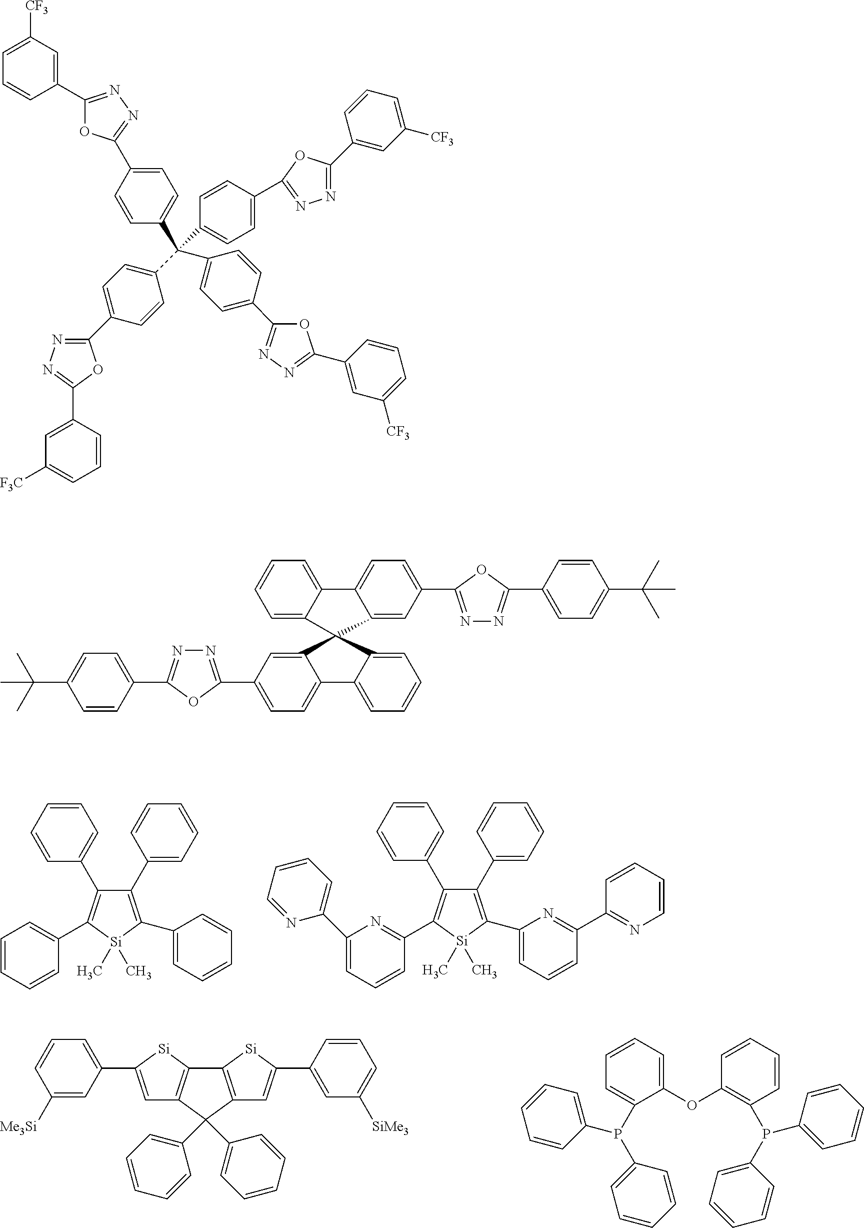

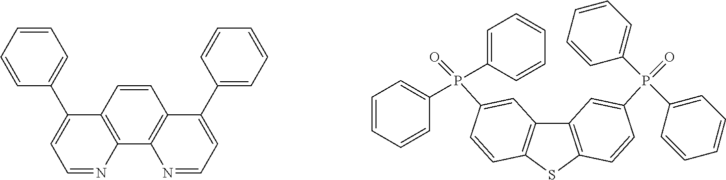 [SMILES: c1ccc(-c2ccnc3c2ccc2c(-c4ccccc4)ccnc23)cc1 ; O=P(c1ccccc1)(c1ccccc1)c1ccc2sc3ccc(P(=O)(c4ccccc4)c4ccccc4)cc3c2c1]

Next, examples of preferred compounds for use as an electron injection material are mentioned below.

LiF, CsF

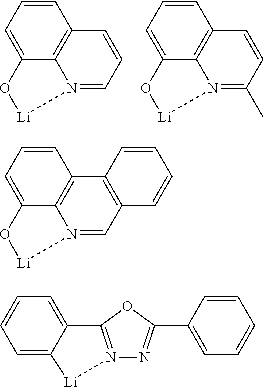

Further, preferred compounds for use as additional materials are mentioned below. For example, these are considered to be added as a stabilization material.

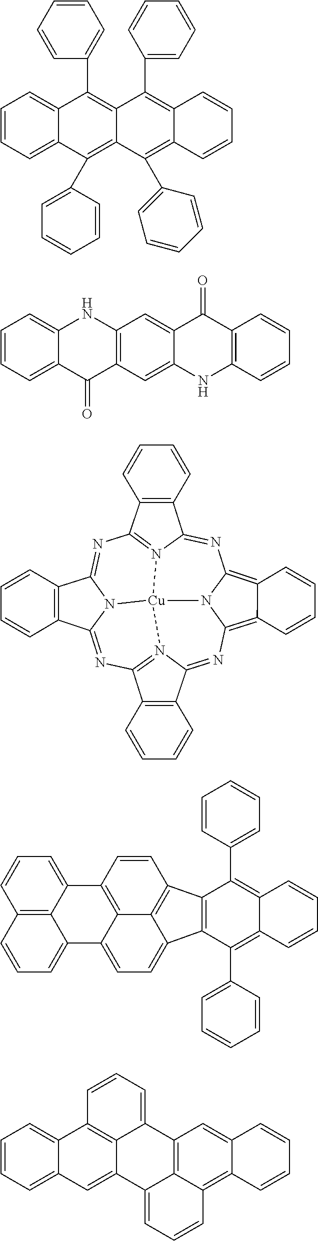

The organic electroluminescent device produced according to the above-mentioned method emits light on application of an electric field between the anode and the cathode of the device. In this case, when the light emission is caused by the excited singlet energy, light having a wavelength that corresponds to the energy level thereof may be confirmed as fluorescent light and delayed fluorescent light. When the light emission is caused by the excited triplet energy, light having a wavelength that corresponds to the energy level thereof may be confirmed as phosphorescent light. The normal fluorescent light has a shorter light emission lifetime than the delayed fluorescent light, and thus the light emission lifetime may be distinguished between the fluorescent light and the delayed fluorescent light.

On the other hand, the phosphorescent light may substantially not be observed with a combination of ordinary organic compounds like the composition of the present invention at room temperature since the excited triplet energy thereof is unstable and is converted into heat and deactivated. For measuring the excited triplet energy of ordinary organic compounds, measurement is possible by observing the emission from the compounds under the condition of extreme low temperatures.

The organic electroluminescent device of the invention may be applied to any of a single device, a structure with plural devices disposed in an array, and a structure having anodes and cathodes disposed in an X-Y matrix. According to the present invention in which a composition containing a donor compound and an acceptor compound to form an exciplex and satisfying specific requirements is contained in the light-emitting layer, an organic light-emitting device having a high light emission efficiency and having a greatly prolonged driving lifetime can be provided. The organic light-emitting device such as the organic electroluminescent device of the present invention may be applied to a further wide range of purposes. For example, an organic electroluminescent display apparatus may be produced with the organic electroluminescent device of the invention, and for the details thereof, reference may be made to S. Tokito, C. Adachi and H. Murata. “Yuki EL Display” (Organic EL Display) (Ohmsha, Ltd.). In particular, the organic electroluminescent device of the invention may be applied to organic electroluminescent illumination and backlight which are highly demanded.

### EXAMPLES

The features of the present invention will be described more specifically with reference to Synthesis Examples and Examples given below. The materials, processes, procedures and the like shown below may be appropriately modified unless they deviate from the substance of the invention. Accordingly, the scope of the invention is not construed as being limited to the specific examples shown below. Hereinunder the light emission characteristics were evaluated using a multichannel spectrometer (available from Hamamatsu Photonics K.K., PMA-12), and an absolute PL quantum yield measuring system (available from Hamamatsu Photonics K.K., Quantaurus-QY Plus), and the device characteristics were evaluated using a source meter (available from Keithley Corporation, Keithley 2400), an absolute external quantum efficiency measuring system (available from Hamamatsu Photonics K.K., C9920-12), and a luminance meter (available from Topcon Corporation, SR-3AR).

The donor compound and the acceptor compounds used in Examples are shown below, and the lowest excited single energy level E_{S1}(M) and the lowest excited triplet energy level E_{T1}(M) of each compound, and the lowest excited single energy level E_{S1}(EX) and the lowest excited triplet energy level E_{T1}(EX) of the exciplex of a combination of a donor compound and an acceptor compound are shown in Table 1.

### Donor Compound

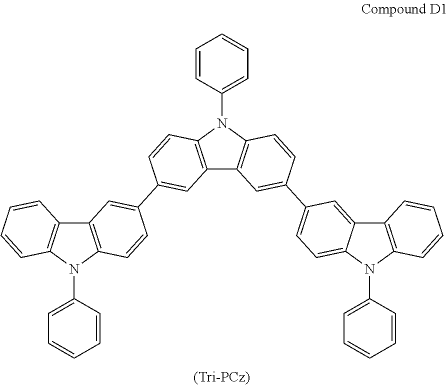 [SMILES: c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1]

### Acceptor Compound

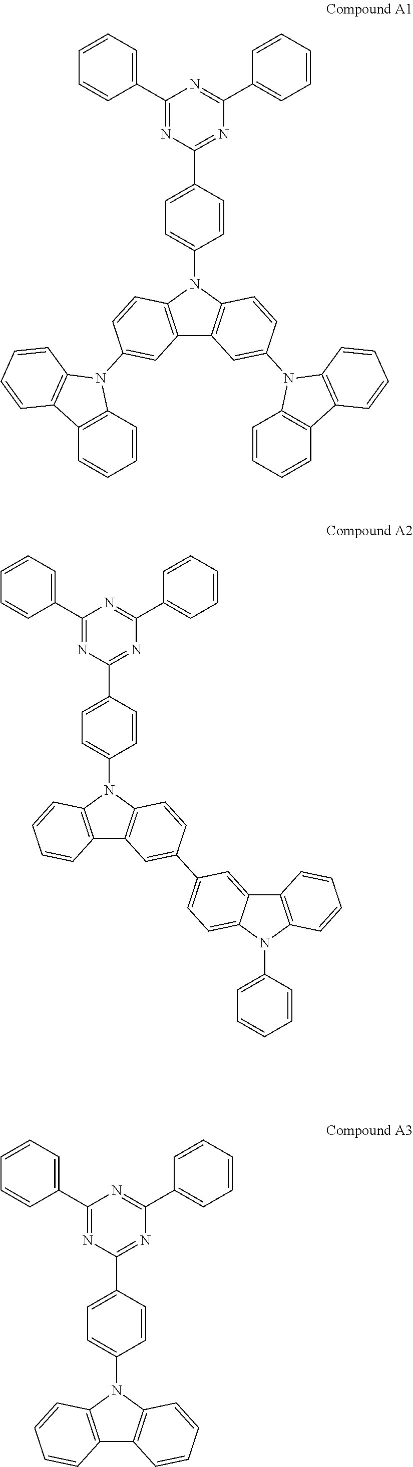 [SMILES: c1ccc(-c2nc(-c3ccccc3)nc(-c3ccc(-n4c5ccc(-n6c7ccccc7c7ccccc76)cc5c5cc(-n6c7ccccc7c7ccccc76)ccc54)cc3)n2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2nc(-c3ccccc3)nc(-c3ccc(-n4c5ccccc5c5ccccc54)cc3)n2)cc1]

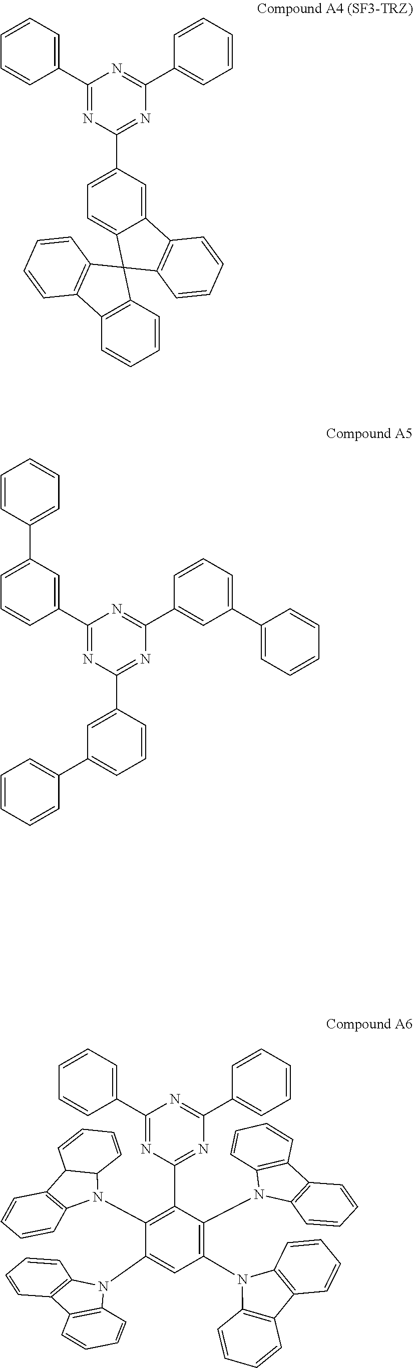 [SMILES: c1ccc(-c2nc(-c3ccccc3)nc(-c3ccc4c(c3)-c3ccccc3C43c4ccccc4-c4ccccc43)n2)cc1 ; c1ccc(-c2cccc(-c3nc(-c4cccc(-c5ccccc5)c4)nc(-c4cccc(-c5ccccc5)c4)n3)c2)cc1 ; C1=CC2c3ccccc3N(c3c(-n4c5ccccc5c5ccccc54)cc(-n4c5ccccc5c5ccccc54)c(-n4c5ccccc5c5ccccc54)c3-c3nc(-c4ccccc4)nc(-c4ccccc4)n3)C2C=C1]

TABLE 1

| Donor | | | | |
|---|---|---|---|---|
| Compound or | | | Mixed Film of Compound D1 and | |
| Acceptor | E_{S1}(M) | E_{T1}(M) | Acceptor Compound | |
| Compound | (eV) | (eV) | E_{S1}(EX) (eV) | E_{T1}(EX) (eV) |
| Compound D1 | 3.33 | 2.76 | — | — |
| Compound A1 | 2.97 | 2.65 | 2.76 | 2.65 |
| Compound A2 | 2.90 | 2.65 | 2.78 | 2.65 |
| Compound A3 | 3.06 | 2.65 | 2.76 | 2.65 |
| Compound A4 | 3.48 | 2.80 | 2.81 | 2.65 |
| Compound A5 | 3.52 | 2.69 | 2.75 | 2.69 |
| Compound A6 | 2.79 | 2.73 | 2.73 | 2.70 |

As shown in Table 1, the combination of the donor compound and the acceptor compound satisfying the requirement A and the requirement B1 of the present invention is a combination of the compound D1 and the compound A1, and a combination of the compound D1 and the compound A2.

### [1] Production and Evaluation of Organic Photoluminescent Device

### Example 1

According to a vacuum evaporation method, the compound D1 and the compound A1 were vapor-deposited on a quartz substrate from different evaporation sources under the condition of a vacuum degree of 5×10⁻⁵ Pa or less to form a thin film in a thickness of 100 nm in which the content of the compound D1 and the compound A1 was 50% by mass each, thereby producing an organic photoluminescent device (PL device).

### Example 2, Comparative Examples 1 to 4

Organic photoluminescent devices (PL devices) were produced in the same manner as in Example 1, except that, as the acceptor compound, an acceptor compound shown in Table 2 was used in place of the compound A1.

TABLE 2

| | Donor Compound | Acceptor Compound |
|---|---|---|
| Example 1 | Compound D1 | Compound A1 |
| Example 2 | Compound D1 | Compound A2 |
| Comparative Example 1 | Compound D1 | Compound A3 |
| Comparative Example 2 | Compound D1 | Compound A4 |
| Comparative Example 3 | Compound D1 | Compound A5 |
| Comparative Example 4 | Compound D1 | Compound A6 |

Of the PL devices produced in Examples and Comparative Examples, the emission spectrum with a 360-nm excitation light and the transient decay curve of emission were measured. Of those 6 types of PL devices, the emission maximum wavelength fell within a range of 499 to 518 nm, and was all shifted toward red than the emission maximum wavelength of a single film of the acceptor compound. This confirms that emission from every PL device was exciplex emission. In addition, from every PL device, delayed fluorescence was observed, and the delayed fluorescence lifetime τ_{d} was within a range of 2.8±0.2 μs, and the rate constant of reverse intersystem crossing k_{RISC} was almost the same on an order of 10⁵ s⁻¹. This suggests that the reverse intersystem crossing process in the exciplex is common to every PL device. Of the PL devices of Example 1 and Comparative Example 1, the phosphorescent spectrum was measured, and was compared with the phosphorescent spectrum of the single film of the acceptor compound. Both PL devices had an emission maximum wavelength common to that of the phosphorescent spectrum of the single film, from which it is known that the excited triplet energy of the exciplex can be transferred to the acceptor compound.

### [2] Production and Evaluation of Organic Electroluminescent Device

### Example 3

On a glass substrate having, as formed thereon, an indium-tin oxide (ITO) anode film having a thickness of 100 nm, thin films were layered according to a vacuum evaporation method under a vacuum degree of 5.0×10⁻⁵ Pa. First, on ITO, HAT-CN was formed in a thickness of 10 nm, and on this, Tris-PCz was formed in a thickness of 30 nm. Next, the compound D1 and the compound A1 were co-vapor-deposited from different evaporation sources to form a layer in a thickness of 30 nm, acting as a light-emitting layer. At that time, the content of the compound D1 and the compound A1 in the light-emitting layer was 50% by mass each. Next, SF3-TRZ was formed in a thickness of 10 nm, and then Liq and SF3-TRZ were co-vapor-deposited from different evaporation sources to form a layer in a thickness of 20 nm. In the layer, the content of Liq and SF3-TRZ was 50% by mass each. Further, Liq was formed in a thickness of 2 nm, and then aluminum (A1) was vapor-deposited in thickness of 100 nm to form a cathode, thereby producing an organic electroluminescent device (EL device).

### Example 4, Comparative Examples 5 to 8

Organic electroluminescent devices (EL devices) were produced in the same manner as in Example 3, except that an acceptor compound shown in Table 3 was used in place of the compound A1.

TABLE 3

| | Materials of Light-Emitting Layer | |
|---|---|---|
| | Donor Compound | Acceptor Compound |
| Example 3 | Compound D1 | Compound A1 |
| Example 4 | Compound D1 | Compound A2 |
| Comparative Example 5 | Compound D1 | Compound A3 |
| Comparative Example 6 | Compound D1 | Compound A4 |
| Comparative Example 7 | Compound D1 | Compound A5 |
| Comparative Example 8 | Compound D1 | Compound A6 |

The organic EL devices produced in Examples and Comparative Examples were tested for measuring the driving time dependency of the light emission intensity at a constant current density of 3.3 mA/cm⁻², and the results are show in Table 3.

As shown in Table 3, the emission intensity decreasing tendency of the EL devices of Examples 3 and 4 was clearly gradual as compared with that of EL devices of Comparative Examples 5 to 8. The half time LT50 of the emission intensity relative to the initial emission intensity was 350 hours in Example 3, 300 hours in Example 4, 125 hours in Comparative Example 5, less than 90 hours in Comparative Example 6 and Comparative Example 7, and 180 hours in Comparative Example 8. Namely, LT50 of the EL devices of Examples 3 and 4 was 2 times or more that of the EL device of Comparative Example 5, and was 3 times or more that of the EL devices of Comparative Examples 6 and 7. From this, it is known that when a compound having a small ΔE_{ST} and having a lowest excited triplet energy level E_{T1}(M) that falls within a range of E_{T1}(EX)−0.2 to E_{T1}(EX)eV is used as one compound to form an exciplex, the driving lifetime of organic EL devices is greatly improved.

Of each EL device of Example 3, Comparative Example 5 and Comparative Example 6, the initial-stage emission spectrum (LT100), the emission spectrum (LT80) at a point at which the emission intensity was 80% in the initial stage, and the emission spectrum (LT50) at a point at which the emission intensity was 50% in the initial stage were measured. Only the organic EL device of Comparative Example 6 using the compound D1 and the compound A4 gave red emission in the emission spectrum at LT80 and LT50 that is not seen in the initial emission spectrum. The red emission is presumed to be derived from an electromer and is a phenomenon that holes were injected into HOMO of the compound A4. The red emission is not seen in the devices (Example 3, Comparative Example 5) using an acceptor compound containing an electron donating group (Compound A1, A3), and this is considered to be because the electron donating group of the acceptor compound functions as a hole acceptor to evade hole injection into the electron accepting unit (here, this is a phenyl group-substituted triazine ring). This indicates that, by introducing an electron donating group into an acceptor compound, the decomposition of the acceptor compound molecule associated with hole injection into an electron accepting unit is prevented to contribute toward improvement of the stability of EL devices.

Further, the devices using the compound A1 or A2 having ΔE_{ST} of not more than 0.35 eV showed a far longer LT50 than the devices using any of the compound A3 to A5 having ΔE_{ST} of more than 0.35 eV, as described above, and it is known that, by defining ΔE_{ST} of the acceptor compound to be not more than 0.35 eV, the stability of EL devices can be greatly improved. Further, this supports that triplet excitons have great influences on degradation of organic EL devices.

The other device characteristics were almost the same for all EL devices. Specifically, regarding the emission spectrum of each EL device, the emission maximum wavelength was 510 nm in Example 3 and Comparative Example 7, 505 nm in Example 4 and Comparative Example 6, 515 nm in Comparative Example 5, and 520 nm in Comparative Example 8, and thus, these were almost the same. Further, the current density-voltage-luminance characteristics and the onset voltage were almost the same for these six EL devices. Moreover, the maximum external quantum efficiency EQEₘₐₓ in the external quantum efficiency-current density characteristics was 14% in Example 4, and about 10% in Example 3 and Comparative Examples 5 to 8, and these were almost the same. These suggest that so far as the electron accepting unit is common to EL devices, a series of light emission process including charge transfer from HOMO of a donor compound to LUMO of an acceptor compound (electron accepting unit), charge recombination, exciplex formation and emission from exciplex may occur in a similar manner, even though ΔE_{ST} is controlled to be not more than 0.35 eV by changing substituents.

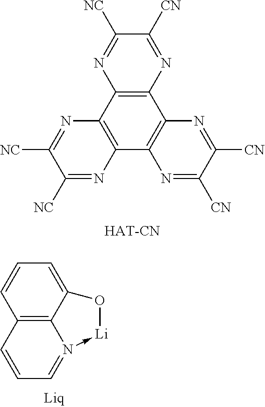

### INDUSTRIAL APPLICABILITY

The composition of the present invention can stably maintain exciplex emission. Accordingly, using the composition of the present invention as a light-emitting layer material of an organic light-emitting device, an exciplex emission device having a long driving lifetime can be realized. Consequently, the industrial applicability of the present invention is great.

### REFERENCE SIGNS LIST

1 Substrate
2 Anode
3 Hole Injection Layer
4 Hole Transport Layer
5 Light-Emitting Layer
6 Electron Transport Layer
7 Cathode

1. A composition containing a donor compound and an acceptor compound to form an exciplex, and satisfying the following requirement A and requirement B1:
(Requirement A)
The donor compound or the acceptor compound is such that the difference between the lowest excited triplet energy level and the lowest excited singlet energy level thereof, ΔE_{ST} is 0.35 eV or less,
(Requirement B1)
The lowest excited triplet energy level E_{T1}(EX) of the exciplex and the excited triplet energy level E_{T1}(M) of the donor compound or the acceptor compound satisfying the requirement A satisfy the following relational expression (unit, eV):
E_{T1}(EX)−0.2≤E_{T1}(M)≤E_{T1}(EX).

2. A composition containing a donor compound and an acceptor compound to form an exciplex, and satisfying the following requirement A and requirement B2:
(Requirement A)
The donor compound or the acceptor compound is such that the difference between the lowest excited triplet energy level and the lowest excited singlet energy level thereof, ΔE_{ST} is 0.35 eV or less,
(Requirement B2)
The phosphorescence emitted from the composition is a phosphorescence from the donor compound or the acceptor compound.

3. The composition according to claim 1, wherein the acceptor compound satisfies the requirement A.

4. The composition according to claim 1, wherein the acceptor compound has a group having a negative Hammett's σp value.

5. The composition according to claim 1, wherein the acceptor compound has a heteroaromatic ring containing a nitrogen atom as a ring skeleton-constituting atom, and a substituted or unsubstituted diarylamino group.

6. The composition according to claim 5, wherein the acceptor compound has a structure represented by the following formula (1): 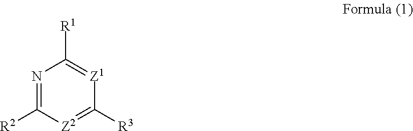
wherein Z¹ represents N or C(R⁴), Z² represents N or C(R⁵), R¹ to R⁵ each independently represent a hydrogen atom, CN, a substituted or unsubstituted alkyl group, a substituted or unsubstituted aryl group, or a substituted or unsubstituted heteroaryl group, and at least one of R¹ to R⁵ is a group having a substituted or unsubstituted diarylamino group.

7. The composition according to claim 6, wherein at least one of R¹ to R⁵ is a group represented by the following formula (2): 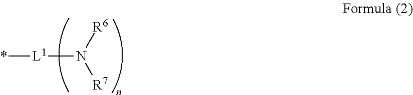
wherein R⁶ and R⁷ each independently represent a substituted or unsubstituted aryl group, L¹ represents a single bond, or a substituted or unsubstituted arylene group, n represents an integer of 1 or more and not more than the maximum number which can be substituted for L¹, * indicates the position bonding to the heteroaromatic ring in the formula (1).

8. The composition according to claim 6, wherein the acceptor compound has two or more substituted or unsubstituted diarylamino groups in the molecule.

9. The composition according to claim 6, wherein the acceptor compound has three or more substituted or unsubstituted diarylamino groups in the molecule.

10. The composition according to claim 1, wherein the donor compound does not have a group having a Hammett's σp value of 0.2 or more.

11. The composition according to claim 1, wherein the donor compound does not have a group having a positive Hammett's σp value.

12. The composition according to claim 1, wherein the donor compound has two or more triarylamine partial structures.

13. The composition according to claim 12, wherein the donor compound has a structure represented by the following formula (3): 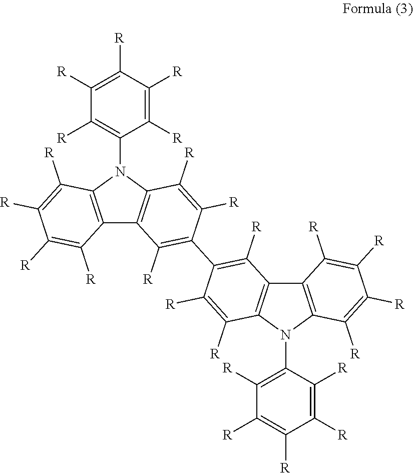
wherein R each independently represents a hydrogen atom or a substituent.

14. The composition according to claim 6, wherein Z¹ and Z² are N.

15. The composition according to claim 1, further containing a fluorescent compound.

16. The composition according to claim 15, wherein the lowest excited triplet energy level E_{T1}(F) of the fluorescent compound and the excited triplet energy level E_{T1}(M) of the donor compound or the acceptor compound satisfying the requirement A satisfy the following relational expression (unit, eV):
E_{T1}(M)≤E_{T1}(F)

17. The composition according to claim 16, wherein the lowest excited triplet energy level E_{T1}(F) of the fluorescent compound and the excited triplet energy level E_{T1}(A) of the acceptor compound satisfying the requirement A satisfy the following relational expression (unit, eV):
E_{T1}(F)−0.2≤E_{T1}(M)≤E_{T1}(F)

18. The composition according to claim 15, wherein the lowest excited singlet energy level E_{S1}(EX) of the exciplex, the lowest excited singlet energy level E_{S1}(F) of the fluorescent compound, the energy Eₚₑₐₖ(EX) obtained from the maximum emission wavelength of the exciplex, and the energy Eₚₑₐₖ(F) obtained from the maximum emission wavelength of the fluorescent compound all satisfy the following relational expressions (unit eV):
E_{S1}(F)<E_{S1}(EX)
Eₚₑₐₖ(EX)<Eₚₑₐₖ(F)

19. The composition according to claim 1, which is filmy.

20. An organic light-emitting device having a light-emitting layer which contains the composition of claim 1.

21. The organic light-emitting device according to claim 20, which emits delayed fluorescence.
